(19) United States
(12) Patent Application Publication
(10) Pub. No.: US 2007/0119369 A1
(43) Pub. Date: May 31, 2007

(54) Method for producing reactive intermediates for transport polymerization

(76) Inventors: Chung J. Lee, Fremont, CA (US); Atul Kumar, Santa Clara, CA (US); Chieh Chen, Palo Alto, CA (US)

Correspondence Address: ALLEMAN HALL MCCOY RUSSELL & TUTTLE LLP, 806 SW BROADWAY, SUITE 600, PORTLAND, OR, 97205-3335, US

(21) Appl. No.: 11/642,383

(22) Filed: Dec. 19, 2006

Related U.S. Application Data
(62) Division of application No. 10/897,797, filed on Jul. 22, 2004.
Application No. 10/897,797 is a continuation of application No. 10/854,776, filed on May 25, 2004.
Application No. 10/854,776 is a continuation-in-part of application No. 10/243,990, filed on Sep. 13, 2002, now abandoned.
Application No. 10/854,776 is a continuation-in-part of application No. 10/141,358, filed on May 8, 2002, now abandoned.
Application No. 10/141,358 is a continuation-in-part of application No. 10/126,919, filed on Apr. 19, 2002, now abandoned.
Application No. 10/126,919 is a continuation-in-part of application No. 10/125,626, filed on Apr. 18, 2002.
Application No. 10/125,626 is a continuation-in-part of application No. 10/115,879, filed on Apr. 4, 2002, now abandoned.
Application No. 10/115,879 is a continuation-in-part of application No. 10/116,724, filed on Apr. 4, 2002, now Pat. No. 6,881,447.
Application No. 10/116,724 is a continuation-in-part of application No. 10/029,373, filed on Dec. 20, 2001, now abandoned.
Application No. 10/029,373 is a continuation-in-part of application No. 10/028,198, filed on Dec. 20, 2001, now Pat. No. 6,797,343.
Application No. 10/028,198 is a continuation-in-part of application No. 09/925,712, filed on Aug. 9, 2001, now Pat. No. 6,703,462.
Application No. 09/925,712 is a continuation-in-part of application No. 09/795,217, filed on Feb. 26, 2001, now Pat. No. 6,825,303.

(51) Int. Cl. C23C 16/00

(52) U.S. Cl. 118/715

(57) ABSTRACT

A method of producing a reactive intermediate having at least two free radicals from a precursor having a general formula of Xₘ—Ar—(CZ′Z″Y)ₙ via a reactor made at least partially of a material M that is reactive with the precursor to produce at least one of MₐY_{b} and M_{c}X_{d} is disclosed. The method comprises heating the reactor, introducing a flow of precursor into the reactor, contacting the precursor with the material M to form the reactive intermediate and at least one of MₐY_{b} and M_{c}X_{d}, and reducing MₐY_{b} to M and a compound comprising Y and/or reducing M_{c}X_{d} to M and a compound comprising X after forming the reactive intermediate and the at least one of MₐY_{b} and M_{c}X_{d}.

### CROSS-REFERENCE TO RELATED APPLICATIONS

The present application is a division of and claims priority under 35 U.S.C. § 120 to U.S. patent application Ser. No. 10/897,797, which is a continuation of, and claims priority under 35 U.S.C. § 120 to U.S. patent application Ser. No. 10/854,776, filed May 25, 2004, which is a continuation-in-part of, and claims priority under 35 U.S.C. § 120 to U.S. patent application Ser. No. 10/243,990, filed Sep. 13, 2002, and U.S. patent application Ser. No. 10/141,358, filed May 8, 2002, all of which are hereby incorporated by reference in their entirety for all purposes.

U.S. patent application Ser. No. 10/141,358 is a continuation-in-part of U.S. patent application Ser. No. 10/126,919, filed Apr. 19, 2002, which is a continuation-in-part of U.S. patent application Ser. No. 10/125,626, filed Apr. 18, 2002, which is a continuation-in-part of U.S. patent application Ser. No. 10/115,879, filed Apr. 4, 2002, which is a continuation-in-part of U.S. patent application Ser. No. 10/116,724, filed Apr. 4, 2002, which is a continuation-in-part of U.S. patent application Ser. No. 10/029,373, filed Dec. 20, 2001, which is a continuation-in-part of U.S. patent application Ser. No. 10/028,198, filed Dec. 20, 2001, which is a continuation-in-part of U.S. patent application Ser. No. 09/925,712, filed Aug. 9, 2001, which is a continuation-in-part of U.S. patent application Ser. No. 09/795,217, filed Feb. 26, 2001. The disclosures of all of the above applications are hereby incorporated by reference in their entirety for all purposes.

### BACKGROUND

Integrated circuits contain many different layers of materials, including dielectric layers that insulate adjacent conducting layers from one another. With each decrease in the size of integrated circuits, the individual conducting layers and elements within the integrated circuits grow closer to adjacent conducting elements. This necessitates the use of dielectric layers made of materials with low dielectric constants to prevent problems with capacitance, cross talk, etc. between adjacent conducting layers and elements.

Low dielectric constant polymers have shown promise for use as dielectric materials in integrated circuits. Examples of low dielectric constant polymers include, but are not limited to, fluoropolymers such as TEFLON ((—CF₂—CF₂—)ₙ; k_{d}=1.9) and poly(paraxylylene)-based materials such as PPX-F ((—CF₂—C₆H₄—CF₂—)ₙ; k_{d}=2.23). Many of these materials have been found to be dimensionally and chemically stable under temperatures and processing conditions used in later fabrication steps, have low moisture absorption characteristics, and also have other favorable physical properties.

One approach for producing poly(paraxylylene) films in the past has been to thermally crack a dimer such as (CH₂—C₆H₄—CH₂)₂ to produce two diradical intermediates of the formula *CH₂—C₆H₄—CH₂*, where “*” denotes an unpaired electron. This process is known as the Gorham method, and is disclosed in U.S. Pat. No. 3,342,754 to Gorham. This process is typically used to prepare PPX ((—CH₂C₆H₄CH₂—)ₙ), (k_{d}=2.7) and some other materials such as PPX-D ((—CH₂C₆H₂Cl₂CH₂—)ₙ) (k_{d}=3.1). However, the dielectric, constants and dimensional/thermal stability of PPX and PPX-D are unsuitable for use in sub-90 micron integrated circuits.

On the other hand, PPX-F, with a dielectric constant of approximately 2.3, is well suited for use in sub-80 micron integrated circuits. However, the generation of a sufficient enough quantity of highly pure *CF₂—C₆H₄—CF₂* diradicals for the commercial use of PPX-F in integrated circuits has posed many problems, as it is difficult to synthesize the dimer (CF₂—C₆H₄—CF₂)₂ in sufficient quantities for commercial applications.

For example, U.S. Pat. No. 3,268,599 to Chow (“the Chow patent”) discloses synthesizing the dimer (CF₂—C₆H₄—CF₂)₂ by trapping the compound in a solvent. However, the solvent-trapped dimer is not in a useful state for commercial scale integrated circuit production. Furthermore, production of the dimer via this method may be prohibitively expensive. As another example, U.S. Pat. No. 5,268,202 to Moore (“the Moore patent”) discloses utilizing a Cu or Zn “catalyst” inside a stainless steel pyrolyzer to generate *CF₂—C₆H₄—CF₂* intermediates from the precursor BrCF₂—C₆H₄—CF₂Br at temperatures of 350-400 degrees Celsius. However, the “catalysts” would actually serve as reactants in this process for the formation of metal bromides, thus clogging the reactor and preventing further debromination. Also, the particular metal bromides formed may migrate to deposition chamber and contaminate the wafer and may be difficult to reduce back to elemental metals.

Another problem with the system disclosed in Moore is that the pyrolyzer and wafer holder of Moore are disclosed as being inside of the same closed system. This may make cooling the wafer (which must be held at a low temperature, for example, −40 degrees Celsius, to deposit the PPX-F film) difficult. Furthermore, if the metal “catalysts” of the Moore patent are not used, the Moore reactor would require a cracking temperature over 800 degrees Celsius to completely debrominate the precursor. At these temperatures, it is likely that many other species may be removed from the precursor besides the desired leaving group, which may create unwanted reactive intermediates that can contaminate the growing PPX-F film and make it unsuitable for use in an integrated circuit. Furthermore, at these temperatures, a significant amount of organic residues, typically in the form of carbon, may accumulate in the reactor, thus harming reactor performance and requiring frequent cleaning.

### SUMMARY

A method of producing a reactive intermediate having at least two free radicals from a precursor having a general formula of Xₘ—Ar—(CZ′Z″Y)ₙ via a reactor made at least partially of a material M that is reactive with the precursor to produce at least one of MₐY_{b} and M_{c}X_{d} is provided. The method comprises heating the reactor, introducing a flow of precursor into the reactor, contacting the precursor with the material M to form the reactive intermediate and at least one of MₐY_{b} and M_{c}X_{d}, and reducing MₐY_{b} to M and a compound comprising Y and/or reducing M_{c}X_{d} to M and a compound comprising X after forming the reactive intermediate and the at least one of MₐY_{b} and M_{c}X_{d}.

### BRIEF DESCRIPTION OF THE DRAWINGS

FIG. 1 shows a schematic view of an exemplary embodiment of a thin film deposition system suitable for depositing a low dielectric constant polymer film.

FIG. 2 shows an isometric view of an exemplary embodiment of a reactor, with an outer heating jacket shown schematically in dashed lines.

FIG. 2A shows an isometric view of the embodiment of FIG. 2, with the heating jacket shown in solid lines.

FIG. 2B is an isometric sectional view of the embodiment of FIG. 2A, taken along line 2B-2B of FIG. 2A.

FIG. 3 shows a side sectional view of the embodiment of FIG. 2.

FIG. 3A shows a side sectional view of another exemplary embodiment of a reactor.

FIG. 4 shows an isometric view of an exemplary heater body for use in embodiment of FIG. 3.

FIG. 4A shows an isometric view of an exemplary heater body for use in the embodiment of FIG. 3A.

FIG. 5 shows a side sectional view of the heater body of FIG. 4.

FIG. 5A shows a side sectional view of the heater body of FIG. 4A.

FIG. 6 shows a magnified front view of the fins of the embodiment of FIG. 4.

FIG. 7 shows an isometric view of a reactor inlet section of the embodiment of FIG. 2.

FIG. 8 shows a side sectional view of the reactor inlet section of FIG. 7.

FIG. 9 shows an isometric view of a reactor outlet section of the embodiment of FIG. 2.

FIG. 10 shows a side sectional view of the reactor outlet section of FIG. 9.

FIG. 11 shows a sectional view of another exemplary embodiment of a reactor.

FIG. 12 shows a graph of an averaged temperature of a gas in a reactor as a function of distance from inlet and flow rate.

FIG. 13 shows another exemplary embodiment of a heater body.

FIG. 14 shows a schematic depiction of a deposition system, with a precursor delivery system shown in solid lines and a reactor regenerating gas delivery system gas flow path shown in dashed lines.

FIG. 15 shows a graph of a uniformity of a low dielectric constant polymer film on a series of wafers as a function of two different cleaning processes.

FIG. 16 shows another exemplary embodiment of a reactor that includes an outlet cleaning subsystem.

FIG. 17 shows a schematic depiction of a deposition system, with a precursor delivery system shown in solid lines, an outlet regenerating gas delivery system shown in dashed lines, and a flow path of regenerating gas shown with solid arrows.

### DETAILED DESCRIPTION OF THE DEPICTED EMBODIMENTS

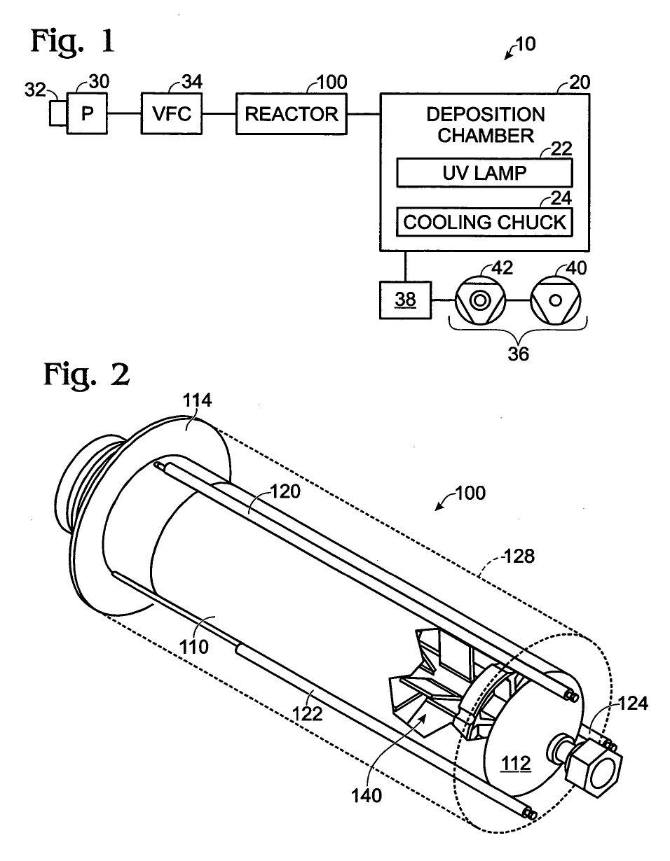

FIG. 1 shows, generally at 10, a vapor deposition system for depositing a polymer dielectric film on a wafer via transport polymerization. System 10 is at times described herein in the context of a system for depositing a PPX-F film, but it will be appreciated that the concepts set forth herein may be extended to any other suitable low dielectric constant polymer film deposition system.

Vapor deposition system 10 includes a vapor deposition chamber 20, and a wafer holder 22 for holding a wafer during deposition. Deposition chamber 20 may also include an energy source, such as an ultraviolet light source 24, for various purposes, for example, for drying a wafer surface before depositing a low dielectric constant film, or for activating the polymerization of a keto-, vinyl- or halo-organosilane layer that may be deposited above or below the low dielectric constant polymer film. Exemplary organosilane materials and uses thereof are disclosed in U.S. patent application Ser. No. 10/816,205 of Chung J. Lee and Atul Kumar, filed Mar. 31, 2004 and titled Composite Polymer Dielectric Film; U.S. patent application Ser. No. 10/816,179 of Chung J. Lee, Atul Kumar, Chieh Chen and Yuri Pikovsky, filed Mar. 31, 2004 and titled System for Forming Composite Polymer Dielectric Film; and U.S. patent application Ser. No. 10/815,994 of Chung J. Lee and Atul Kumar, filed Mar. 31, 2004 and titled Single and Dual Damascene Techniques Utilizing Composite Polymer Dielectric Film, the disclosures of which are hereby incorporated by reference.

Vapor deposition system 10 also includes a precursor source 30 for holding a precursor compound. For example, where system 10 is for depositing a PPX-F film, precursor source 30 may be configured to hold a precursor of the general formula XCF₂—C₆H₄—CF₂X′, wherein X and X′ are each leaving groups that may be removed from the precursor to generate the diradical intermediate *CF₂—C₆H₄—CF₂*. A heater 32 may be provided to heat precursor source 30 to generate a vapor pressure of the precursor within the source.

Vapor deposition system 10 also includes a reactor 100 for converting the precursor molecules into a flow of gas-phase free radical intermediates. The flow of precursor vapor into reactor 100 may be controlled in any suitable manner. In the depicted embodiment, the flow of precursor vapor into reactor 100 (and reactive intermediate into deposition chamber 20) is controlled by a vapor flow controller 34 and one or more valves (not shown). The outflow from reactor 100 is directed into deposition chamber 20, where the reactive intermediates may condense on a wafer positioned on wafer holder 22 and polymerize to form a low dielectric constant polymer film. To help the reactive intermediates condense on the wafer surface, wafer holder 22 may be configured to cool the wafer surface to a suitably low temperature. Additionally, to prevent film deposition inside the gas line between reactor 100 and the deposition chamber, the gas line and chamber wall temperatures should be at least 25 to 30° C., preferably 30 to 50° C.

Deposition chamber 20 is maintained under a vacuum by pumping system 36, which may include one or more roughing pumps 40 to pump the deposition chamber to a vacuum, and one or more high vacuum pumps 42 to maintain a desired vacuum for deposition of the polymer film. An exhaust trap or treatment system, such as a cold trap 38 or a scrubber (not shown), may be provided to treat or trap chamber exhausts.

For reactor 100 to be useful in forming reactive intermediates for transport polymerization, the reactor should generate intermediates with high efficiency (>99% yield) and substantially no unwanted side products (>99% purity). Known commercial tubular thermal reactors, or pyrolyzers, although useful for converting the precursor dimer (CH₂—C₆H₄—CH₂)₂ to two diradical intermediates, have been found to be unsuitable for forming reactive intermediates from many other monomer precursors. One reason for this is that the temperature within the commercially available reactors typically has too much positional variation. For example, when a commercially available hollow tubular pyrolyzer having a length of eight inches and an inner diameter of 1.2 inches was heated to 480 degrees Celsius under a vacuum of 10 mTorr for the removal of Br from the precursor BrCF₂—C₆H₄—CF₂Br, it was found that a large fraction of the interior volume of the pyrolyzer had temperatures much cooler than 480 degrees. Due to poor heat transfer under vacuum, only a small region of the inner wall in the downstream areas within the pyrolyzer was at the desired temperature. Thus, bromine atoms may not be removed from a large fraction of precursor molecules flowing through the reactor, leading to low yields of reactive intermediate.

To attempt to solve these problems, the pyrolyzer may be heated to a higher temperature, for example 800 degrees Celsius or higher, so that the temperature within the entire volume of the pyrolyzer is greater than 480 degrees Celsius. This may achieve complete removal of bromine from the precursor. However, at the higher temperatures within the pyrolyzer, other bonds besides the C—Br bonds will likely be broken. This may cause the formation of thick carbon deposits (“coke”) within the pyrolyzer, which can further insulate the center region of the pyrolyzer and make the positional temperature variation within the pyrolyzer even greater. Furthermore, the breaking of other bonds besides the C—Br bond may result in a variety of different reactive intermediates being introduced into deposition chamber 20, and thus may result in unwanted cross-linking, the formation of many polymer chain ends, and other such problems. The resulting films may have poorer thermal stability and inferior electrical properties compared to the desired films.

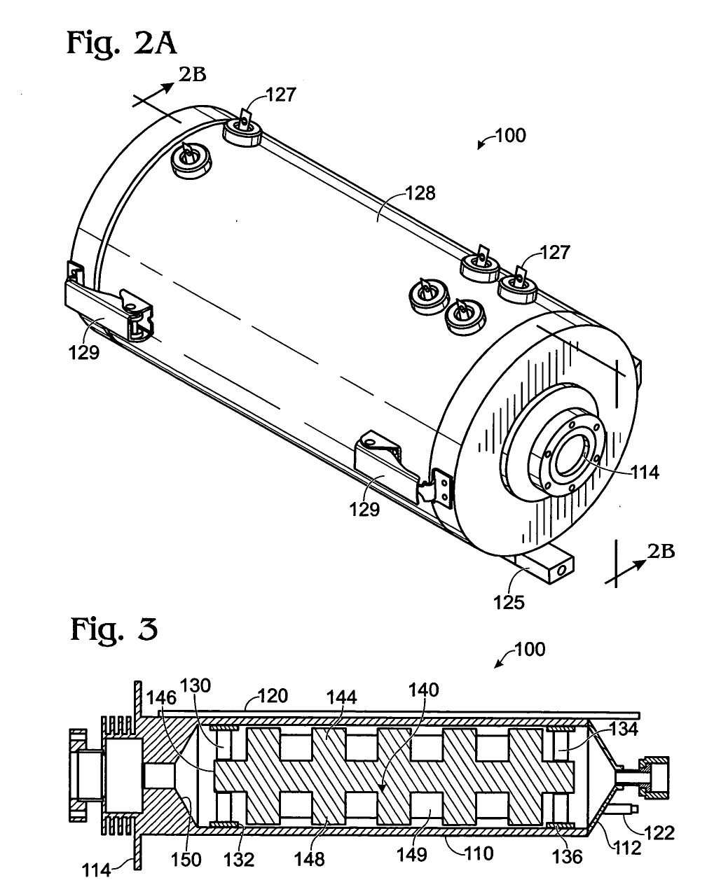

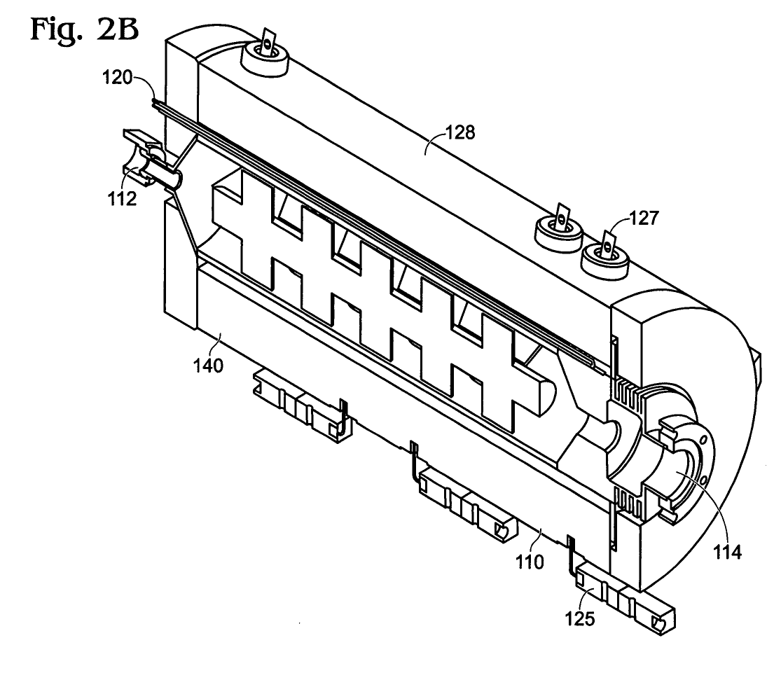

As described in more detail below, the reactor of deposition system 10 cracks precursors with high efficiency and with essentially no unwanted side products to produce high-quality low dielectric constant thin films for semiconductor applications via transport polymerization. FIG. 2 shows, generally at 100, a first exemplary embodiment of such a reactor. Reactor 100 includes an outer container 110, a heater body 140 disposed within the outer container, an inlet section 112 for admitting a flow of precursor molecules, and an outlet section 114 for passing an outflow of reactive intermediates created in the reactor.

Outer container 110 helps to keep the interior of reactor 100 at a desired vacuum, typically 0.01-2 Torr. Also, outer container 110 and heater body 140 cooperate to evenly heat precursor molecules introduced into the reactor to crack the precursor molecules with a high yield while avoiding unwanted side reactions. Furthermore, both outer container 110 and the heater body 140 may be configured to react with leaving groups on the precursor molecules, thereby lowering the energy of the cracking reaction, and thus lowering the temperature at which the cracking takes place. Additionally, the reactive outer container 110 and heater body 140 may trap the leaving groups and thus help prevent contamination of the growing polymer film with the leaving groups. In these embodiments, the outer container 110 and heater body 140 may also be configured to be easily regenerated between processing runs. Each of these features is described in detail below.

Reactor 100 may be configured to process any suitable precursor from which reactive intermediates may be formed. Examples include, but are not limited to, precursors having the general formula:
X′ₘ—Ar—(CZ′Z″Y)ₙ (I)
In this formula, X′ and Y are leaving groups that can be removed to form a free radical for each removed leaving group, Ar is an aromatic group or a fluorine-substituted aromatic group bonded to m X′ groups and n CZ′Z″Y groups, and Z′ and Z″ are H, F or C₆H₅₋ₓFₓ(x=0, or an integer between 1 and 5). For example, where m=0 and n=2, removal of the leaving group y from each CZ′Z″Y functional group yields the diradical Ar(CZ′Z″*)₂. Compounds in which Z′ and Z″ are F may have lower dielectric constants and improved thermal stability. Examples of suitable leaving groups for X′ and Y include, but are not limited to, ketene and carboxyl groups, bromine, iodine, —NR₂, —N⁺R₃, —SR, —SO₂R, —OR, ═N⁺═N—, —C(O)N₂, and —OCF—CF₃ (wherein R is an alkyl or aromatic group). The numbers m and n in formula (I) may independently be either zero or an integer, and (n+m) is equal to or greater than two, but no greater than the total number of sp² hybridized carbons in the aromatic group that are available for substitution.

Ar in formula (I) may be any suitable aromatic group. Examples of suitable aromatic groups for Ar include, but are not limited to, the phenyl moiety C₆H₄₋ₙFₙ (n=0 to 4); the naphthenyl moiety C₁₀H₆₋ₙFₙ (n=0 to 6); the di-phenyl moiety C₁₂H₈₋ₙFₙ (n=0 to 8); the anthracenyl moiety C₁₂H₈₋ₙFₙ (n=0 to 8); the phenanthrenyl moiety C₁₄H₈₋ₙFₙ (n=0 to 8); the pyrenyl moiety C₁₆H₈₋ₙFₙ (n=0 to 8); and more complex combinations of the above moieties such as C₁₆H₁₀₋ₙFₙ (n=0 to 8). Isomers of various fluorine substitutions on the aromatic moieties are also included. More typically, Ar is C₆H₄,C₆F₄, C₁₀F₆, or C₆F₄—C₆F₄.

Low dielectric constant polymer film 16 may also be made from a precursor having the general formula
X′ₘArX″ₙ (II)
wherein X′ and X″ are leaving groups, and Ar is an aromatic or fluorine-substituted aromatic. The numbers m and n each may be zero or an integer, and m+n is at least two, but no greater than the total number of sp² hybridized carbon atoms on Ar that are available for substitution. For example, polyphenylene (—(C₆H₄)—) and fluorine-substituted versions thereof may be formed from a precursor having general formula (VI). Removal of the leaving groups X′ and/or X″ may create the diradical benzyne (*C₆H₄*), which can then polymerize to form polyphenylene. Other aromatic groups besides the phenyl moiety that may be used as Ar in formula (VI) include, but are not limited to, the naphthenyl moiety C₁₀H₆₋ₙFₙ (n=0 to 6); the diphenyl moiety C₁₂H₈₋ₙFₙ (n=0 to 8); the anthracenyl moiety C₁₂H₈₋ₙFₙ (n=0 to 8); the phenanthrenyl moiety C₁₄H₈₋ₙFₙ (n=0-8); the pyrenyl moiety C₁₆H₈₋ₙFₙ (n=0-8); and more complex combinations of the above moieties such as C₁₆H₁₀₋ₙFₙ (n=0-10).

In particular, some polymers with fluorine atoms bonded to sp² hybridized and hyperconjugated sp³-carbon atoms, including but not limited to PPX-F (—(—CF₂—C₆H₄—CF₂—)—), may possess particularly advantageous thermal, chemical and electrical properties for use in integrated circuits. However, as described above, PPX-F has proven to be difficult to utilize in a commercially feasible manner for integrated circuit production. For example, the dimer (CF₂—C₆H₄—CF₂)₂ has so far proven to be difficult to synthesize in sufficient quantities for large-scale integrated circuit production. Furthermore, cracking of the monomer BrCF₂—C₆H₄—CF₂Br in a stainless steel reactor to produce the diradical *CF₂—C₆H₄—CF₂*, as disclosed in the above-described Moore patent may result in the formation of large quantities of coke if the temperatures disclosed as necessary in the absence of a Zn or Cu “catalyst” (which are actually reactants, and not catalysts) are used. Furthermore, if the Zn or Cu “catalyst” is used, the “catalysts” may become deactivated by leaving groups, and the resulting Zn or Cu bromides may contaminate the growing polymer film.

Another problem with cracking brominated precursor molecules having fluorine atoms on hyperconjugated sp³ carbon atoms is that the C—Br bonds and the C—F bonds have cracking temperatures that are relatively close together. If the temperature within the reactor is too high or has too much variation, it is possible that either the temperature is too low in places to crack C—Br bonds, or too high in places to avoid cracking C—F bonds (or sp² hybridized C—H bonds). In either case, the result is that yields of reactive intermediates decrease while yields of unwanted contaminants increase.

One difficulty in achieving temperature uniformity is due to the poor conductive and convective heat transfer modes in the vacuum environment within a thermal reactor at low pressures. Temperature uniformity may be increased by increasing the pressure within reactor 100. However, this may increase the number of collisions between reactive intermediate molecules, and thus may cause reactive intermediates to bond together to form larger intermediates. These larger molecules have higher melting points than the desired reactive intermediates, and thus may condense onto a cooled wafer surface within deposition chamber 20 and form powders. This may cause the growth of a lower quality dielectric film. Furthermore, the larger intermediates may deposit on the walls of the reactor, and thus may increase coke formation within the reactor.

Reactor 100 overcomes the problem of temperature uniformity by more carefully controlling radiative heat transfer within the reactor, while decreasing conductive heat transfer between structures within the reactor, in particular, between outer container 110 and heater body 140. Radiative heat transfer is the transfer of heat via electromagnetic waves. Because radiative heat transfer does not rely on the direct transfer of kinetic energy between colliding or coupled atoms or molecules, radiative heat may be distributed evenly throughout an evacuated volume more easily than convective or conductive heat. This may help to lessen problems with hotspots where one location within reactor 100 is significantly hotter than another location within the reactor, and therefore may help to reduce coke formation, unwanted side reactions, etc. It will be appreciated, however, that energy may be imparted to precursor molecules via both radiation and conduction, as precursor molecules traveling through the reactor will pick up energy by colliding with the inner wall of container 110 and with heating body, and also may absorb infrared radiation emitted by the surfaces within the reactor. Furthermore, the surfaces within reactor 100 may be formed at least partially from a material that can chemically react with the leaving groups at temperatures below the thermal cracking temperature. This allows the precursors to be cracked at temperatures low enough to avoid significant coke formation. This feature is described in more detail below.

Specifically, reactor 100 achieves a high level of temperature uniformity by the irradiation of heater body 140 with IR radiation emitted by or transmitted through outer container 110. Over a short period of time, heater body 140 and outer container 110 reach a condition of thermal equilibrium in which each part emits an amount of IR radiation roughly equal to what it absorbs. Careful design of outer container 110, the heater body and the heating mechanism used to heat the reactor may allow a substantially similar flux of IR radiation to be achieved throughout the inner volume of the reactor. Furthermore, outer container 110 and heater body 140 may each be made of a material with high thermal conductivity. In this way, heat can easily spread along outer container 110 and heater body 140, further helping to maintain temperature uniformity. This makes it possible to remove a desired leaving group with a high level of specificity with a lessened amount of unwanted side reactions. Furthermore, because the temperatures of the surfaces within the reactor are substantially similar, fewer problems with hotspots and the associated coke formation may be encountered.

The surface finish of outer container 110 and heater body 140 can affect the emissivity of the surfaces. As such, a rough surface can be used on heater body 140 and/or outer container 110 to increase the emission of radiation energy and thereby increase heat transfer. However, this may increase deposits in certain locations, and therefore smooth surfaces may be used in an alternative embodiment.

Referring again to FIG. 2, reactor 110 is shown as having a cylindrical shape. While this example shows a cylindrical reactor, other geometries can be used if desired, including but not limited to oval, square, hexagonal, or other polygons. The reactor can be in any shape or configuration that provides the desired precursor residence time and temperature control under vacuum conditions described herein. The description and equations described below provide further details of how varying geometry, temperature, mass flow rate, etc., can affect the system and reactor design.

Reactor 100 may be heated in any suitable manner that provides for the desired radiative heating effects within the reactor, and the temperature within the reactor may be controlled in any suitable manner. For temperature sensing and control, reactor 100 may include one or more temperature sensor taps, which can be used to enable a measurement of temperature at one or more points along the length of reactor 100. The depicted embodiment includes three temperature sensors taps (120, 122, and 124), however, it will be appreciated that either more or fewer may be used. This temperature measurement can then be used to control the heater to maintain a desired temperature via feedback control. The sensor taps may be welded to outer container 110, or any other suitable connection may be used.

Likewise, any suitable type of temperature sensor may be used to detect the temperatures within reactor 100. Examples include, but are not limited to, thermocouples, thermal expansion gradient bimetallic sensors, resistance thermometers (conductive sensors), and/or thermistors (bulk semiconductor sensors). In the depicted embodiment, the three temperature sensor taps are equally positioned around outer container 110 (see the right side view in FIG. 3, for example), although unequal positioning may also be used. For an exemplary reactor having a length of 17 inches, the sensor taps may be positioned along the axis of the outer container at 4.5 inches, 10.5 inches, and 14.6 inches.

Reactor 100 may be heated via a heat source that is in direct contact with outer container 110, or via a source that is spaced from the outer container. FIGS. 2A and 2B show one example of a suitable heat source for heating reactor 110, in the form of an electrically powered heating jacket 128 that substantially surrounds outer container 110. The heating elements within heating jacket 128 may be in direct contact with, or in close proximity to, outer container 110. In some embodiments, outer container 110 may be made from a material with strong IR absorption and emission characteristics. In this case, as heating jacket 128 heats outer container 110, the interior walls of outer container 110 emit IR radiation to transfer heat to the inner heating body via radiative energy transfer. When heating body 140 is cold relative to outer container 110, it will absorb more radiation than it emits, thereby increasing in temperature. As it approaches the temperature of the interior walls of outer container 110, it emits more and more radiation. At steady state, the rates of emission of both heating body 140 and outer container 110 will be approximately the same as rates of absorption of energy. Suitable IR-opaque materials for the construction of outer container 110 and heating body 140 are discussed in more detail below.

In other embodiments, outer container 110 may be made of a material transparent or translucent to IR radiation. In these embodiments, heating jacket 128 may contain, or may be used to heat, a black body (not shown) positioned around outer container 110, which then emits IR radiation to heat heating body 140. Examples of suitable materials for such a black body include, but are not limited to, silicon carbide. Such a black body may emit IR radiation in the ranges from 700 to 1200 cm⁻¹, although radiation outside of this wavenumber regime also may be emitted. Examples of suitable IR transparent materials from which outer container 110 may be made include, but are not limited to, quartz and sapphire.

Besides electrical resistive heaters, other suitable heaters may be used in place of (or in addition to) the above-described electrical resistive heater to heat outer container 110 and/or heater body 140. Other suitable heaters include, but are not limited to, plasma heaters, microwave heaters, tungsten and tungsten/halogen lamps, iron/chromium/aluminum heaters, nickel/chromium heaters, and/or combinations thereof. Tungsten and tungsten-halogen heaters can provide up 60 Watts/in² to 200 Watts/in² or higher of power and can ramp up in 1-2 seconds, but may need air or water cooling to operate. Single-wound iron-chromium-aluminum or nickel-chromium heating coils can ramp up in 10 to 20 second and have an output of up to 60 Watts/in or higher of power; while a double wounded heating coil can ramp up in 5 seconds. Suitable commercial IR heaters are available from many sources, for example, from Solar Products Inc. of Pompton Lakes, N.J.

Referring again to FIG. 2A, the depicted heating jacket 128 is held in place around outer container 110 via clamps 129. However, any other suitable mechanism may be used to secure a heater around outer container 110. Further, heating jacket 128 includes one or more electrical connectors 125 and 127 for powering the heater. FIG. 2B shows a cut-away view illustrating further details and interior structure of the various parts of outer container 100, heater body 140, and heating jacket 128.

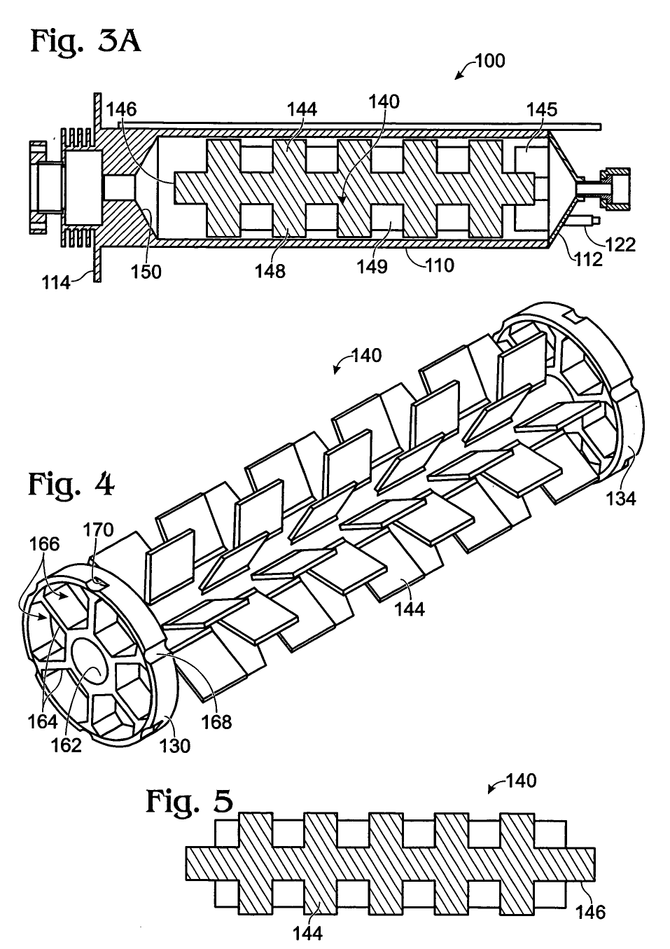

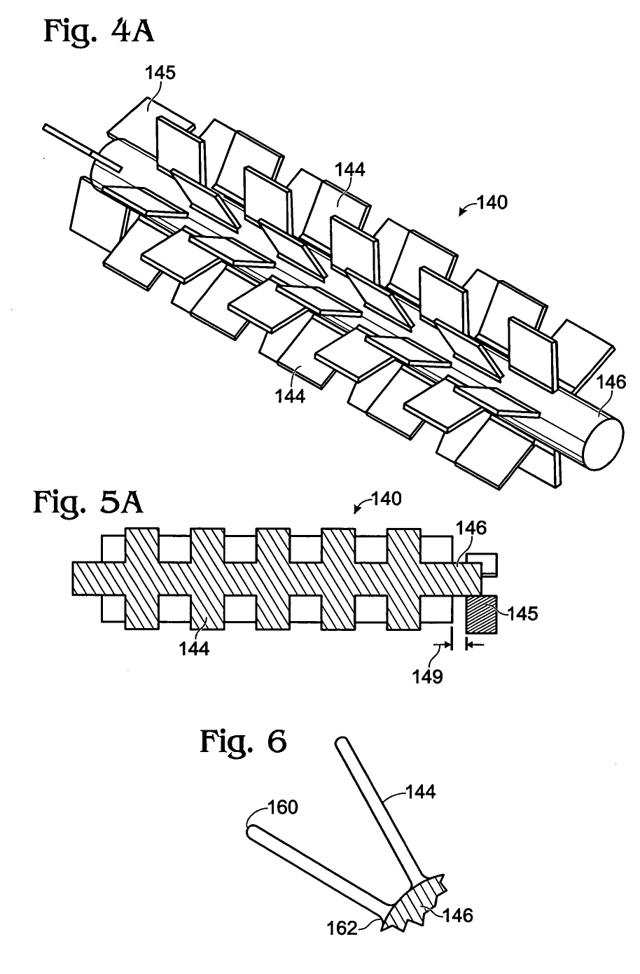

FIG. 3 shows a side sectional view of reactor 100 and heater body 140 (which is described in more detail below with regard to FIGS. 4-6). FIG. 3 is generally to scale, showing a 12-inch long outer container 110 having a 3.5-inch diameter although these dimensions can be varied, if desired. The length may be selected to provide a desired residence time in the reactor, based on the mass flow rate of precursors. Further, the inlet hole size of 112, and the outlet hole size of 114 may be selected to provide a desired precursor mass flow rate. In the embodiment depicted in FIG. 3, the minimum inlet cross-sectional area is smaller than the minimum cross-sectional outlet tube, as described in more detail below. Further, the conical shape of outlet section 114 at enlarged area 150 may help to collect and direct reactive intermediates to the outlet to be transported to the deposition chamber.

The depicted heater body 140 includes a plurality of fins 144, and an inner core 146 which supports the fins and from which the fins radiate. Much of the radiant energy emitted by (or through) outer container 110 is absorbed by inner core 146 of heater body 140. This absorption of radiant energy heats core 146 evenly along its length. This heat is conductively transferred through the core and into fins 144, where it is radiated outwardly toward the outer container and other fins. In this manner, core 146 acts as a sort of heat sink that directs heat to fins 114 for radiation. Fins 144 also absorb energy radiated by the inner walls of outer container 110, although possibly to a lesser extent than inner core 146.

As described below, in one example, six radial fins (a “set” of fins) are positioned around inner core 146 of heater body 144 in a radial direction at equal angle increments. Also, in this example, nine sets of fins are positioned along the axis of inner core 146, providing a total of 54 fins. The fins are shown as rectangular in shape, however various other shapes could be used, if desired, including but not limited to half circles, trapezoids, etc.

The depicted arrangement of fins helps to achieve a high degree of temperature uniformity within reactor 100, on the order of ±10-20° C. Specifically, the angle between fins can be selected to provide a desired amount of radiation absorption and a desired pattern of emission, thereby providing a desired temperature profile in the reactor. The angle between the fins can also be selected so that as the precursors flow through the reactor, the mean free path is such that the molecules will collide with the large surface area side of the fins (or with the interior wall of outer container 110, or the shaft of heater body 140), to enable heat transfer to precursors, and to enable a desired chemical reaction with the surfaces within reactor 100 to take place. Further, by placing the fins with the narrow edge facing the direction of flow, a low flow restriction is obtained, thereby enabling the desired throughput in a compact system. This also illustrates the advantage of varying the fin locations from one radial set to the next, as the number of fins can be reduced while still providing the desired reaction capability.

Fins 114 may be spaced inside the reactor to create an alternating heating and mixing zones 148 and 149 inside the reactor, as shown in FIG. 3. The term “heating zones” as used herein signifies the surface area of fins 144 used for transferring thermal energy to precursor molecules as the molecules collide with the fins. The term “mixing zones” implies the space between the fins in which precursor and intermediate molecules are mixed by the fluid flow patterns created by fins 144. Fins 144 also are spaced axially and radially in such a manner as to help reduce temperature variation along the length and radius of the reactor.

Furthermore, reactor 100 may include multiple heating zones to help prevent gas choking (i.e. a significantly impeded gas flow) within the reactor. Gas choking of reactive intermediates or other reaction products inside the reactor can create excess coke formation due to long exposure of these chemicals at high temperature, and should be reduced or avoided, if possible. One approach to avoid or reduce this formation uses a multiple-zone heater design, for instance, having a preheating and a cracking zone. The preheating zone may have a longer path length and/or a cooler temperature than the cracking zone. Inside a preheating zone, the precursors are warmed up to a temperature close to the desired cracking temperature. Once the precursors in the pre-heater reach a desired temperature, the heated precursors can then be quickly released into, or flow into, a second heating zone for cracking. Using this two-zone heater, the precursor and reactive intermediate molecules may spend less time in the higher cracking zone, which may help to reduce excess carbon formation inside the reactor. Thus, by reducing the heating path and temperature variation in the cracking zone of a reactor, chemical conversion efficiency can be maximized with lower amounts of carbon formation.

FIG. 3 also shows one exemplary method of coupling heater body 140 to outer container 110. In this embodiment, heater body 140 is in contact with outer container 110 only at its ends, and is held in position within outer container via coupling devices 130 and 134. Coupling devices 130 and 134 locate and secure heater body 140 in reactor 100, thereby allowing a gap to be maintained between the ends of fins 144 and the interior wall of outer container 110. This gap, along with the low pressure in the reactor, provides at least partial thermal conductive insulation between the heater body 140 and the outer container 110. This insulation reduces conductive and convective heat transfer within reactor 100, thereby allowing the radiative energy transfer to provide a more uniform temperature profile in the reactor. Furthermore, coupling devices 130 and 134 may each contact thermally insulating barriers 132 and 136, respectively, within reactor 100, which further help to reduce conductive heat transfer between outer container 110 and heater body 140. In an alternative embodiment, insulators 132 and 136 are removed and coupling devices 130 and 134 are constructed of insulating material, such as a ceramic material, to reduce heat transfer by conductance. However, in some embodiments, a small portion of heater body 140 may be in thermally conductive contact with outer container 110, as described below with regard to FIG. 3A.

By substantially conductively insulating coupling devices 130 and 134 with thermal barriers 132 and 136 and with the gap between fins 144 of heater body 140 and outer container 110, the primary mode of heat transfer between outer container 110 and heater body 140 is made to be radiative. Furthermore, careful design of the configuration of outer container 110 and heater body 140 helps to control the distribution of heat in these parts and achieve a substantially similar flux of thermal radiation throughout the reactor.

The gap between the ends of fins 144 and the inner wall of outer container 110 may have any suitable dimensions. In some embodiments, the gap between fins 144 and the inner wall of outer container 110 has a diameter of between approximately 0.06 and 0.08 inch, and more specifically approximately 0.068 inch, although various other size gaps can be used, such as, for example: 0.1 inch, 0.01-0.05 inch, 0.06-0.1 inch, etc.

Coupling devices 130 and 134 include one or more open sections configured to allow flow through reactor 100. These sections are described in more detail below in the context of FIG. 4. The depicted coupling devices 130 and 134 provide support for heater body 140 in all radial directions. This allows reactor 100 to be mounted in substantially any orientation without causing heater body 140 to come into thermal contact with outer container 110.

FIG. 3 also shows an enlarged area 150 of outlet section 114, created by forming a conical section in section outlet 114. By using a conical section, a greater surface area for a given diameter can be achieved. Enlarged area 150 can be used for trapping some deposits generated during deposition and cleaning. Also, as discussed in more detail below, these deposits can be removed after a number of wafer depositions, for example, from 1500 to 2000 wafer depositions, by an oxidative gas or plasma treatment.

Referring now to FIG. 3A, an alternative embodiment is illustrated with an additional set of fins 145 is provided on heater body 140 to couple heater body 140 to one of inlet section 112 and outlet section 114. In this embodiment, additional fins 145 may be coupled to inlet section 112 or outlet section 114 by welding, or by any other suitable method. This allows heater body 140 to be mounted within outer container 114 while being wholly supported by either inlet section 112 or outlet section 114. While this may provide some contact for thermal conductance between fins 145 and outer container 110 via inlet section 112 or outlet section 114, fins 145 can be designed such that the effect is minor compared to the radiant heat transfer between outer container 110 and heater body 140 to reduce this conductive heat transfer to insignificant levels. In the depicted embodiment, fin set 145 has only three fins positioned 120 degrees apart to reduce the surface contact between heater body 140 and inlet section 112, however, it will be appreciated that any other suitable arrangement may be used.

Referring now to FIG. 4, an isometric view of heater body 140 from FIG. 3 is shown with coupling devices 130 and 134. Further, an exemplary configuration of fins 144 is shown. In this example, nine sets of radial fins are used, with each set equally positioned about the diameter of inner container core 146. The nine sets are also equally spaced axially along the length of heater body 140. In the example shown in FIG. 4, the rear edge position of one set of fins along the axial length aligns with front edge of the next set of fins, although the two sets are rotationally offset from each other. Each set of fins has 6 radial fins, for a total of 54 fins in this example.

Fins 144 are positioned to provide efficient radiant energy absorption, emission and transfer. In the example of FIG. 4, each radial set of fins contains six equally spaced fins radially spaced by 60 degrees. Further, every other radial set of fins is offset by an angular increment of half the angular spacing of the fins, thirty degrees in this case. However, other spacing could be used. For example, each set of fins could be offset by fifteen degrees from the previous set. Each fin of the depicted embodiment is a thin rectangular section protruding with the thin edge facing the flow direction, thereby providing low flow restriction.

While this example shows each radial fin extending outward at ninety degrees relative to the shaft, other angles could be used. For example, the fins could be angled to slant to one side at an angle of forty-five degrees, or be positioned tangential to inner core 146. Also, different sets of fins could be positioned at a different relative angle to the shaft.

Coupling devices 130 and 134 are shown as cylindrical sections with a center hole 162 for mounting to core 146. Further, coupling devices 130 and 134 each have six sectional holes (one of which is denoted at 166) with six internal walls (one of which is denoted at 164) to permit passage of precursor and reactive intermediate molecules through the coupling devices. In one example, the internal walls of coupling devices 130 and 134 align with one of the fin sets. As discussed above, coupling devices can be made from materials with low thermal conductivity to reduce conductive heat transfer from the heater core 140 to outer container 110. Coupling devices 130 and 134 may have one or more recess areas (full recess 168 and partial recess 170), as illustrated in FIG. 4, for aligning the coupling devices and fixing the heater body 140 to the outer container 110. Alternatively, the bottom coupling devices 130 can also be can be replaced with fins 145, as shown in the FIG. 4A. In this case, the top coupling device 134 may be omitted.

Referring now to FIG. 4A, an isometric view of heater body 140 from FIG. 3A is shown with additional fin set 145. As illustrated in FIG. 4A, fins 145 are positioned at the bottom end of the heater core 146, with an angle of 120 degrees between the 3 fins. The radial height, axial width, and thickness of the depicted fins 145 are the same as fins 144, although they could be modified, if desired. Further, in the depicted embodiment, there is an axial space 149 between the last set of fins 144 and fins 145. Alternatively, no space could be used.

Reactor 100 may be configured to provide a desired surface-to-volume ratio of internal surface area for reaction to provide a compact design. For example, reactor 100 may have a volume of less than or equal to approximately 60 cm³, and a surface area of 300 cm²-500 cm². In another embodiment, the volume of reactor 100 is a least 10 cm³ and the total interior surface area is at least 1000 cm². It will be appreciated that these dimensions are merely exemplary, and that reactor 100 may have any other suitable volume and internal surface area.

FIG. 5 shows a side sectional view of heater body 140. Inner core 146 is shown as solid, although it may also have a hollow, semi-hollow, or other structure having internal voids. Exemplary relative dimensions of fins 144 are also shown. Fins 144 may have any suitable dimensions. In one example, fins 144 have a thickness of approximately 0.081 inch, a radial height of approximately one inch, and a width of approximately one inch. Thus, in this case, the thickness is less than both the height and width. Further, approximately a one-inch gap is provided between sets of fins at the same radial position, and adjacent sets of fins (that are radially offset) have substantially no axial gap between them. While these dimensions provide an example, the exact dimensions can vary depending on a number of factors, including the desired flow throughput and allowed temperature variation within the reactor.

Also, while the fins are shown as having a substantially constant thickness and width along the flow direction, (see FIG. 6) these dimensions may also vary along this direction. For example, the fins could have a partial or total wedge shape, such that the upstream thickness is less than the downstream thickness (or vice versa). Also, the radial height could increase along the flow direction. Further, different fins could be made with different axial widths.

FIG. 5A shows a side sectional view of the heater body 140 from FIG. 3A is shown, illustrating additional fins 145. FIG. 5A shows that approximately half the width of additional fin set 145 extends beyond core 146, to help reduce conductive heat transfer from fins 145 to core 146, and to hold core 146 spaced above the inlet or outlet section above which it rests.

FIG. 6 shows a detail view of two fins 144 from adjacent fin sets, as indicated in FIG. 5. In the depicted embodiment, each fin 144 is manufactured with a rounded external edge 160 and fillets 162 at the junction of the fin and the core 146. However, fins 144 may have any other suitable edge profiles. In this example, the two fins 144 are separated by an angle of 30 degrees, but the fins may have any other suitable angular offset. In one embodiment, the fins are integrally formed or molded in the heater core. In an alternative embodiment, each fin is welded to core 146.

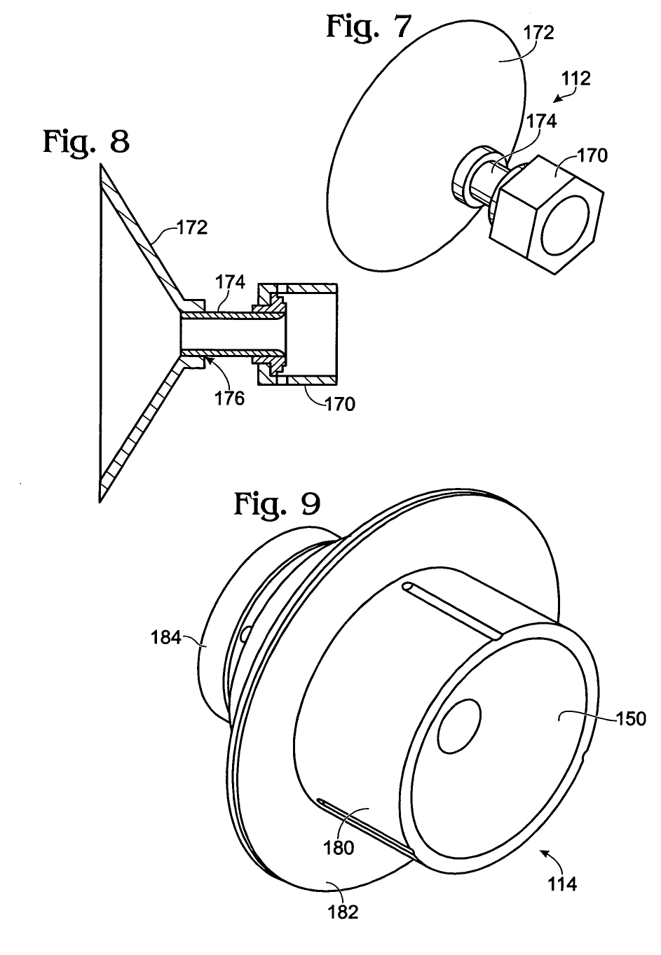

Referring now to FIG. 7, an isometric view of inlet section 112 is shown, having a flow inlet 170 in the form of a female nut, a connection tube 174 connected to the flow inlet, and a reducing cone 172 where flow inlet 170 is adapted to be coupled to precursor source 30. Reducing cone 172 of inlet section 112 can be welded to outer container 110 after heater body 140 is mounted in outer container 110. Alternatively, inlet section 112 can be bolted to, or integrally formed with, with outer container 110. In one example, inlet section 112 is the last piece welded into the system after the inner core/fins are installed inside outer container 110.

FIG. 8 shows a detailed view of inlet section 112. The following are example dimensions that can be used, however as noted above, the size of the system can be varied. The outer diameter of reducing cone 172, in this example, is approximately 3.5 inches with an approximate depth of one inch. The inner diameter of connection tube 174 is approximately ½ inch, and the connection tube has a length of approximately one inch. In one example, inlet section 112 is formed by welding the junction between the connection tube 174 and reducing cone 172 at location 176. Alternatively (or in addition), a press fit can be used, as with the mounting between connection tube 174 and flow inlet 170.

Referring now to FIG. 9, an isometric view of outlet section 114 is shown, including enlarged area 150 of conical section 180, ring section 182, and deposition outlet 184. As shown in FIG. 9, the enlarged flow area at deposition outlet 184 compared with the reduced diameter in the upstream portion of conical section 180 (at 186) creates a nozzle. Even though the minimum cross sectional area at the outlet is greater than the minimum cross sectional area of the inlet, the volumetric gas flow rate and velocity at the outlet can be substantially greater than that at the inlet due to the heat addition and temperature rise in the reactor, as described by the equations discussed below, even if the outlet cross sectional area is greater than the inlet area.

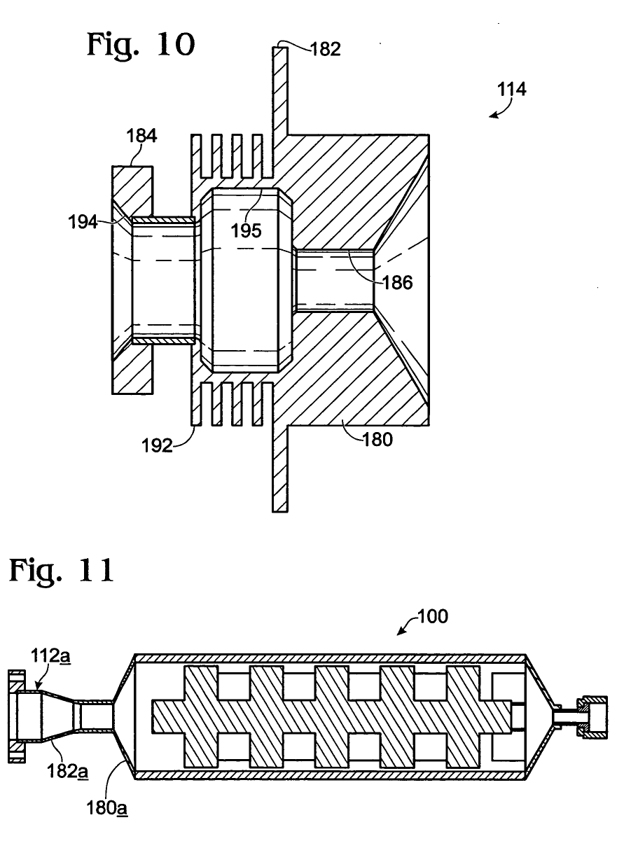

FIG. 10 shows a side sectional view of outlet section 114. One set of example dimensions is as follows. The outer diameter of ring section 182 is approximately 5 and ⅝ inches. The front view of outlet section 114 shows the outer diameter of conical section 180 being approximately 3.5 inches, which is welded (or otherwise connected) to ring section 182 at location 190. Conical section 180 is also shown having circular ribs 192 having a thickness of approximately ⅛ of an inch. The total length of section 114 is approximately 3.9 inches. Deposition outlet 184 is welded (or otherwise connected) to conical section 180 at location 194. The smallest inner diameter in section 180 is approximately 0.75 inches, which then expand to a hole of approximately 2.25 inches, shown at location 195. Then, the opening contracts down again to approximately 1.38 inches before opening up to approximately 1.5 inches at the outlet. It will be appreciated that these dimensions are merely exemplary, and that outlet section 114 may have any other suitable dimensions.

FIG. 11 shows, generally at 112a, another embodiment of a suitable outlet section for reactor 100. Outlet section 112a includes a conical section 180a that helps direct reactive intermediates out of the reactor and that helps increase the velocity of the outlet flow. Outlet section 112a also includes a nozzle section 182a positioned downstream of conical section 180a. Nozzle section 182a has a substantially smoothly increasing cross-sectional area moving along the direction of gas flow. Enlarged nozzle section 182a, like section 150 of FIG. 9, may function to collect deposits resulting from reactions between leaving groups and the walls of the reactor, as well as organic residues resulting from the periodic oxidative cleaning of reactor.

The above figures and description describe several example reactor designs that can be used for processing the precursors. However, the exact and relative dimensions of the various components of the reactor can be modified while still providing the desired result. For example, the fin and internal reactor surface area, the flow area, the length of the reactor, the shape and orientation of the heat transfer surface, and/or the configuration of the reactor, including combinations thereof, can be varied to affect the processing of the precursors and the results obtained. The following description describes one example design methodology for selecting and sizing the various components to provide a desired mass flow rate of the processed gas at the reactor outlet and inside the reactor.

The state condition of the processing gas at inlet (including inlet pressure (Pᵢₙ), inlet temperature (Tᵢₙ)) of the reactor may be characterized by the following conditions: Pᵢₙ=1 torr=1 mm Hg, Tᵢₙ=25° C., Volume flow rate, \dot{V}=1 to 6 sccm, and Molecular weight=350 gm/mole. The state condition of the processing gas at outlet (including outlet pressure (Pₒ), outlet temperature (Tₒ)) may be characterized by the following conditions: Pₒ=20 to 30 mTorr. Tₒ=650° C. The mass flow rate at the inlet can be found from the volumetric flow rate of 1 sccm=1×10⁻⁶ scmm, taking the time derivative of the ideal gas law, and assuming the pressure and temperature are relatively constant, which gives:

$$\begin{matrix}\dot{n} = \frac{P \dot{V}}{RT} \\ = \frac{1.01 \times {10}^{5} \times 1 \times {10}^{- 6}}{8.3145 \times ( 273 + 25 )} \\ = .0000408 mol e \text{/} min \\ = 0.000000679 mole \text{/} s\end{matrix}$$

The mass flow rate range (using the range of volumetric flow cited above) can then be calculated as:
\dot{m}ₘᵢₙ=350\dot{n}=0.000237 gm/s=0.000000237 kg/s
\dot{m}ₘₐₓ=350\dot{n}×6=0.00142 gm/s=0.00000142 kg/s
The specific volume (v) at a temperature of T=90° C. and pressure of 1 Torr can also be calculated as:

$$\begin{matrix}v = \frac{RT}{p} \\ = \frac{8.3145 \times ( 273 + 90 )}{\frac{1}{760} \times 1.01 \times {10}^{5}} \\ = 24 {m}^{3} \text{/} mole\end{matrix}$$

From this, the volume flow rate at inlet can be found using the relationship of: \dot{V}=\dot{n}v, which gives the volume flow rate range as:
\dot{V}ₘᵢₙ=\dot{n}ₘᵢₙv=0.000000670×24=0.000016 m³/s
\dot{V}ₘₐₓ=6×0.000016=0.000096 m³/s
The cross-sectional area at the inlet, in m², can be calculated from the inlet and outlet diameter at the end of the reducing cone 172 (including the cross sectional area of the fins, for the case of six fins) as follows:

$$\begin{matrix}A = \frac{π}{4} ( {d}_{o}^{2} - {d}_{i}^{2} ) - 6 \times h \times t \\ = \frac{π}{4} ( {3}^{2} - {1}^{2} ) - 6 \times 1 \times 0.081 \\ = 5.8 {in}^{2} \\ = 0.00374 {m}^{2}\end{matrix}$$

From this, the flow velocity range at inlet can be found using the relationship:

$$\dot{v} = \frac{\dot{V}}{A} ,$$

which gives:
\dot{v}ₘᵢₙ=0.0043 m/s=0.43 cm/s
\dot{v}ₘₐₓ=0.0258 m/s=2.58 cm/s

At the outlet, a similar set of calculations can be used. In particular, the specific volume near outlet at mid range pressure (e.g., Po=25 mTorr) and outlet temperature of 650° C. can be found using the ideal gas law as:

$$\begin{matrix}v = \frac{RT}{p} \\ = \frac{8.3145 \times ( 273 + 650 )}{\frac{25 \times {10}^{- 3}}{760} \times 1.01 \times {10}^{5}} \\ = 2310 {m}^{3} \text{/} mole\end{matrix}$$

From this, the volume flow rate and flow velocity near outlet are found to be almost 100 times larger than that at the inlet. Specifically, based on the above parameters, the range is:
\dot{v}ₘᵢₙ=0.43×2310/24=41.4 cm/s
\dot{v}ₘₐₓ=6×41.4=248.4 cm/s

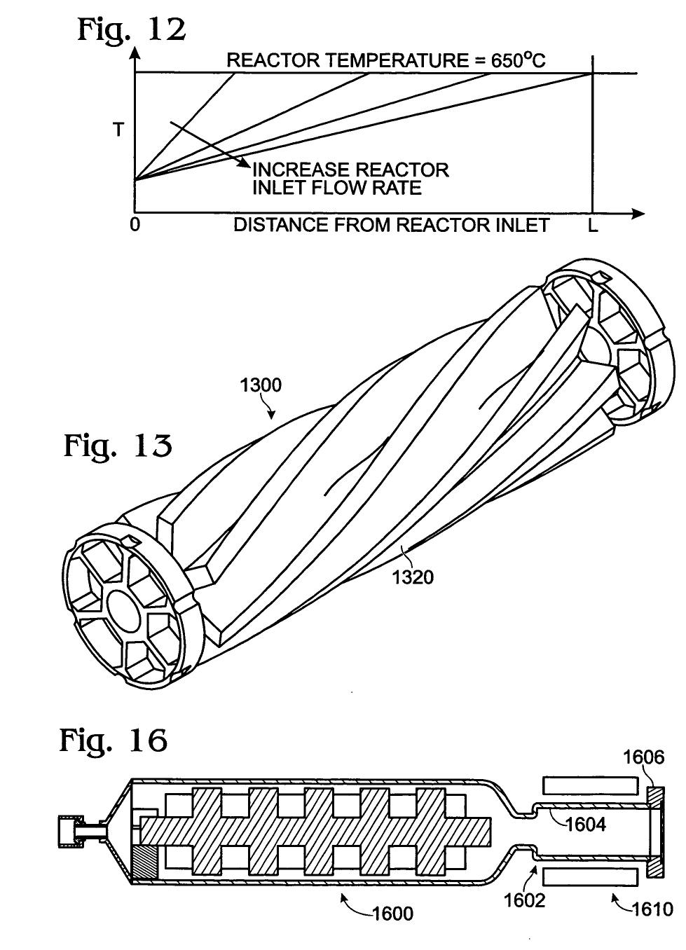

As described above, the temperature increase of the precursors through the reactor can require a certain amount of residence time. FIG. 12 shows the precursor temperatures within reactor 100 as a function of distance from the inlet and the flow rate. If the velocity or the flow rate is too high, the majority of the processing gas may not have sufficient time to reach the required temperature to react and to release the leaving groups. As such, the reactor geometry can be selected to provide sufficient residency time to heat the precursor to a desired processing temperature before it outlets the reactor.

Based on the above flow calculations, the flow area can be calculated and selected to provide a minimum time to keep the processing gas inside the reactor for the reaction process to complete. In addition, the surface area is also as important factor in the calculations and selection, as surface area can enhance the heat transfer process and thereby affect the temperature profile as a function of distance from the inlet. Further, the fin surface may be inclined relative to the flow direction to enhance contact heat transfer. Also, the diameter of the reactor may be made smaller to cope with the flow rate range of 1 sccm to 6 sccm. Further still, the flow rate could be higher than 6 sccm, and thus the reactor could be modified to accommodate this higher flow rate by changing the diameter, length, fins, etc.

The above analysis is based on the flow rate condition and several assumptions regarding the chemical reactions. However, other theories may be used to describe the physical and chemical processes, and thus the present application is not limited to the above description.

In addition to the various alternative reactor designs discussed above, still other options area available. In one alternative approach, porous SiC disks can be used as a heater body in the reactor. In another, an alternate heater body design comprises spherical closely packed balls having, for example, a diameter that ranges from 0.5 mm to 10 mm, wherein the closely packed balls are packed with a packing density, for example, in the range from about 50% to about 74%. Other heating bodies include porous metallic disks, and metallic disks with small holes. Because each of these heater bodies may touch the inner wall of the outer cylinder, they should be made of a material with excellent thermal conductivity to avoid large temperature deviations and hot spots within the reactor.

Where the heater body is made of a porous material, the material may have a skeletal structure, and the skeletal wall may have surfaces with few to no voids, inclusions and metallic impurities. A porous medium can be particularly useful if it has a reticular structure of open, duode-cahedronal-shaped, cells connected by continuous solid metal or ceramic ligaments. Such a matrix of cells and ligaments can be highly, or completely, repeatable, regular, and uniform throughout the entirety of the medium. These porous media can have good thermal conductivity and structural integrity. Further, these media can be rigid, highly porous, and permeable and have a controlled density or ceramic per unit volume. Density of useful media varies from 5 to 90%, preferably from 30 to 50% for a combination of high permeability and thermal conductivity. The porous material may have any suitable pore density, for example, from 5 to 150 pores per inch (ppi), and more specifically from 20 to 60 ppi. These porous media may have high surface area to volume ratios ranging from 10 to 80 cm²/cm³, thus providing for a compact reactor.

The inside diameter of the pores may have any suitable size. Examples of suitable sizes include, but are not limited to, sizes ranging from 0.01 to 5 mm, or from 0.5 to 3 mm. Although not wanting to be bound by theory, when the inside diameter of these pore is less than the mean free path of the precursors, more collision between the precursors and inside surfaces of the heater bodies can be expected. However, when the pore size is too small, excess surface areas in gas flow or diffusion direction can generate too many collisions between precursors or their reaction products with the heater bodies inside the reactor. When pore sizes are much smaller than the mean free path of these chemicals, forward diffusion of these chemicals can be impeded (“gas choking”, described above), and coke formation can becomes a problem under high reactor temperatures. Thus, as described above, by reducing a heating path and temperature variation in the cracking zone of the reactor, chemical conversion efficiency can be maximized with lower amounts of carbon formation. In a multiple-zone reactor where porous heater bodies are employed, the heater bodies in the pre-heating zone may consist of smaller pores, whereas those in the cracking zone may have bigger pores.

In still another alternative, the heater body 140, including fins 144, may take the form of a porous metal.

Still another alternative embodiment for heater body 140 is shown in FIG. 13 in which heater elements 1320 are shown on heater body 1300. In this example, the fins traverse the length of the reactor, spiraling about 90-120 degrees in one example.

As mentioned above, at least some interior surfaces of reactor 100 (which include the inner surfaces of outer container 110, the outer surfaces of heating body 140, and the inner surfaces of inlet section 112 and outlet section 114) may be made of a material that is capable of undergoing a chemical reaction with the leaving group (or groups) on the precursor molecules to generate the reactive intermediates for transport polymerization. In a traditional thermolytic reactor (or pyrolyzer), precursors gain thermal energy during heating by colliding with the heating elements or heater bodies inside the reactor. Once a precursor molecule acquires sufficient thermal energy to meet or exceed the energy of activation, thermal cracking or breakage of the chemical bonds occurs. However, the use of a metal reactant may allow cracking of a precursor at a much lower temperature than in a pure thermolytic reactor. For example, in the absence of a metal reactant, the di-bromo PPX-F precursor thermally cracks at approximately 680° C. However, iron reacts with the di-bromo precursor when the interior iron surface temperature reaches about 420° C., nickel reacts with the precursor at around 480° C., and copper reacts with the precursor at around 320 to 350° C. under a few milli Torrs.

In the discussion below, the term “metal reactant” is used to denote a metal capable of undergoing a chemical reaction with a leaving group on the precursor. Such a metal may be a catalyst, in that the metal is regenerated at a temperature lower than the reactor operating temperature, or may be a reactant that binds the leaving groups until a later regeneration step at a higher temperature and/or under a different gaseous environment. In either case, the presence of the metal reactant may lower the activation energy of the precursor cracking reaction, thereby allowing the reactor to be run at a lower temperature. This may help to avoid coke formation within the reactor, may improve yields of reactive intermediates, and may help to decrease unwanted side reactions. Typically, the metal reactant is of a high purity to avoid the formation of any unwanted contaminant compounds.

Various other terms are used are used below to describe the chemical characteristics of the metal reactant. Some of these terms are as follows:

A “reacted metal reactant” as used herein is a metal that has reacted with a precursor to generate a desired intermediate. Where the leaving group is a halide, this term may be used to describe the metal halide resulting from the reaction.

A “reaction temperature” (Tᵣ) is a temperature at which a leaving group reacts with a metal reactant within a reactor in a sufficient quantity to produce a commercially useful amount of reactive intermediate.

A “regenerating temperature” (T_{rg}) as used herein is a temperature capable of regenerating a metal reactant from a reacted metal reactant.

A “regenerating gas” as used herein is a gas capable of regenerating a metal reactant from a reacted metal reactant (or from an otherwise oxidized metal reactant, as described in more detail below). In one embodiment, a regenerating gas or gas mixture (for example, hydrogen and argon) is used to regenerate a metal reactant from a metal halide. In another embodiment, a regenerating gas is used to regenerate a metal reactant from another oxidized metal reactant, such as a metal oxide.

Where a metal reactant is used inside of reactor 100, the reactive intermediates are generated by a chemical reaction between the leaving group and the metal reactant at a reaction temperature Tᵣ. For instance, many of the above-disclosed di-bromo precursors can react with a metal reactant at a suitably low Tᵣ to avoid significant coke formation and to generate the desired reactive intermediate. This reaction is illustrated in equation (1) as follows. In this equation, Y is a halogen; Z, Z′, Z″ and Z′″ are each a hydrogen, a fluorine, an alkyl, and/or an aromatic; and Ar is an aromatic.
nYZZ′CArCZ″Z′″Y+nM→n*ZZ′CArCZ″Z′″*+nMY₂ (1)

The metal bromide of reaction (1) may be regenerated to make reactor 100 useful for further conversion of precursors into intermediates. This may happen spontaneously where T_{rg} (or a decomposition temperature T_{d}) is below Tᵣ, or may be accomplished as needed by a suitable regeneration reaction performed at an effective T_{rg}. Reaction (2) illustrates this principle in the context of the reduction of the metal halide product of reaction (1) with hydrogen, as follows:
MY₂+H₂(g)→M+2HY(g) (2)
In the particular example of NiBr₂, the reaction thermodynamics for reaction (2) are as follows. At a regeneration temperature T_{rg} of 500° C., the regeneration reaction enthalpy (“dH”)=−130.4 kJ/mol, the Gibb's Free Energy (“dG”)=20.3 kJ/mol, and the reaction constant k=4.23E-2.0. It is noteworthy that that H₂ and HY are each in a gas phase.

Similarly, the metal halide MY₂ also may be regenerated in come cases by heating to a decomposition temperature T_{d} according to reaction (3), as follows:
MY₂→M+Y₂(g) (3)

In considering a material to be used as a reactive metal within reactor 100, at least four criteria may be considered. First, the effective reaction temperature Tᵣ between the precursor and the metal should be under 800° C. (and preferably 700° C.) under a vacuum ranging from 0.001 to a few Torrs. Second, in some embodiments, a material with a T_{d} equal to or lower than the effective Tᵣ may be selected. Although not wanting to be bound by theory, under this ideal condition, the metal is a catalyst. Third, a metal whose halide has a regenerating temperature T_{rg} above, or approximately equal to, Tᵣ may be selected. In some embodiments, T_{rg} is not more than 400° C., and in others, not more than 200° C. above the Tᵣ. In these embodiments, the leaving group remains bonded to the reactive metal until the reactive metal is regenerated in a later step. Also, in these embodiments, where T_{rg}=Tᵣ, the reactor can be set at Tᵣ, and the regeneration of reactor 100 can be done at the same temperature by using a reactor regenerating subsystem, as described in more detail below. Fourth, the melting temperature Tₘ of the metal halide may be at least 100 to 200, and preferably 300 to 400° C., higher than the Tᵣ. A metal halide that has a Tₘ too close to the reaction temperature Tᵣ may not be stable inside reactor 100, and may thus tend to migrate or diffuse outside the reactor and contaminate the equipment or the semiconductor wafers being processed.

Table I below shows the melting temperature Tₘ and reaction temperature Tᵣ of some exemplary transition metals bromides. This table also indicates whether T_{d} is above or below (i.e. a catalyst) Tᵣ. From Table I, it can be seen that the bromides of Ti, Fe, Pt, Cr, Co, W and Ni have a suitably large spread between Tᵣ and Tₘ for use as reactive metals within reactor 100. The symbol “d” means that the material decomposes at the stated temperature.

TABLE I

| Metal Bromide | Tᵣ (° C.) | Tₘ (° C.) | Is T_{d} < Tᵣ ? |
|---|---|---|---|
| TiBr₂ | | d > 500 | Yes |
| TiBr₄ | | 39 | |
| CrBr₂ | 480-500 | 842 | |
| CrBr₃ | 480-500 | 812 | No |
| FeBr₂ | 380˜420 | d˜684 | Yes |
| FeBr₃ | 380˜420 | d˜200 | |
| CoBr | 450-480 | 678 in N₂ | |
| NiBr₂ | ˜480-500 | 963 | No |
| CuBr₂ | ˜320-350- | 498 | |
| CuBr | ˜320-350 | 504 | |
| ZnBr₂ | 280-300 | 394 | |
| TaBr₃ | | d˜265 | |
| TaBr₄ | | 400 | |
| TaBr₅ | | 280 | |
| WBr₆ | | 232 | |
| PtBr₂ | | 250 | Yes |
| AuBr | | 115 | Yes |
| AuBr₃ | | 97.5 | |
| AgBr | | 432 | Yes? |

Because Au and Pt bromides are self-regenerating at temperatures above the T_{d} (e.g. 115 and 250° C., respectively) of their reaction products, Au and Pt may be utilized as catalyst-style reactants when using a di-bromo precursor. In addition, since Pt and Au are noble metals, organic residues inside reactor 100 can be removed using oxidative processes without causing oxidation of the Au and Pt. For example, a reactor with Pt interior surfaces operated at temperatures from 280 to 400° C. promotes coke formation at a relatively low rate during leaving group removal, and also causes automatic regeneration of the metal by decomposition of the metal bromide. Periodically passing oxygen through the reactor at a temperature of over 400° C. and then purging with an inert or reducing gas can remove organic residue from inside the reactor. However, gold and platinum are expensive, and thus may not be suitable for commercial-scale reactors.

From Table I, it can be seen that Fe and Ti also may be suitable metal reactants for reacting with the di-bromide precursors disclosed earlier herein. This is because reactor 100 can be used to remove bromine leaving groups at temperatures around 680 to 700° C. and 500 to 550° C., which are near the respective decomposition temperatures T_{d} of Fe- and Ti-bromides, respectively. However, it is important to take note that when reactor temperatures are maintained above 500° C. over time, “coke” formation can be expected. Consequently, a periodic oxidative decomposition step to remove organic residues may be needed when Fe or Ti metal reactants are used.

Cr or Ni may be more suitable than Fe or Ti as metal reactants. This is because these metals react with the di-bromine precursors at lower temperatures than iron and titanium, and thus may help avoid coke formation. For example, Ni reacts with di-bromine precursors, such as (Y—CZZ′-Ar—CZ″Z′″-Y; Y═Br), at reaction temperatures Tᵣ above 480° C. This may be low enough to avoid high rates of coke formation. Furthermore, nickel bromide can be effectively reduced to nickel using as little as 4 to 10% of hydrogen in argon at regenerating temperatures T_{rg} ranging from 500 to 650° C. for few minutes. Furthermore, nickel bromide has a melting temperature Tₘ as high as 963° C., and thus is very stable inside the reactor during the debromination and regeneration reactions.

However, the Ni tends to oxidize when oxygen is used to clean organic residues from inside reactor 100. One way to extend the life span of the nickel within reactor 100 is to use the reactor at about 480° C. for generation of intermediates from di-bromo precursors and then regenerate the nickel from the nickel bromide at 600° C. or above using hydrogen. At 480° C., the coke formation rate is relatively low if the reactor is designed carefully and the residence time of the precursor is short, because coke formation normally starts at higher than 450 to 480° C. under desirable feed rates for precursors. Furthermore, to improve the throughput of this type of reactor, multiple reactors may be employed in a parallel arrangement in a single deposition system. With this configuration, some reactors may be regenerated while others are producing reactive intermediates.

Silver may be a less practical metal reactant for use within reactor 100. This is because the reaction temperature Tᵣ for silver is approximately 200 to 350° C., which may be too close to the melting temperature Tₘ (450° C.) of silver bromide. Similarly, cobalt, aluminum, copper, tungsten and zinc may not be suitable for use in some systems, as the Tₘ of the corresponding bromides may be too low, or too close to the Tᵣ. However, in some embodiments that utilize an outer cylinder 110 that transmits light, a silver coating formed on the inside of the reactor wall and heater elements may be useful due to the photosensitivity of silver bromide. For example, the temperature of the reactor may be held at 250° C. to generate reactive intermediates, and the silver can be regenerated by exposing the silver bromide to high intensity visible light. Likewise, other metals also may be regenerated by exposing their corresponding metal bromides to visible or UV light via a photolytic reaction, and thus may be useful as interior surface material for the reactor of this invention.

In yet other embodiments, a multiple step regeneration process may be used to regenerate the reacted metal reactant. These are shown in the following reactions (4) and (5):
MY₂+X₂(g)→MX₂+Y₂(g); k=k₁ (4)
MX₂+H₂(g)→M+2XH(g); k=k₂ (5)
wherein M is a transition metal such as Ni; Y=Cl, Br or I; and X is fluorine. For the specific case where MY₂ is nickel bromide, the thermodynamics of these reactions at 500° C. are as follows: dH=−416 kJ/mol; dG=−398 kJ/mol; and k₁=8.2E26 for reaction (4); and dH=106 kj/mol, dG=−17.7 kj/mol and k₂=1.6E1.0 for reaction (5). It is noteworthy that that X₂, Y₂, H₂ and HX are all in a gas phase.

Another example of a multi-step regeneration process is shown as a two-step process in reactions (6) and (7). This process may be used where reaction (6) is used to oxidize organic residues, and where reaction (7) is then used to reduce metal oxides to regenerate the metal reactant.
mMY₂+nX₂(g)→MₘX₂ₙ+mY₂; k=k₃ (6)
MₘX₂ₙ+2nH₂→mM+2nH₂X(g); k=k₄ (7)
wherein M is a transition metal such as Ni; Y is Cl, Br or I; and X is oxygen. For the specific case of NiBr₂ at 500° C. (and where m=1 and n=1), the reaction thermodynamics are as follows: dH=0.33 kJ/mol; dG=−31.33 kJ/mol and k₃=1.29E2 for reaction (6); and dH=−9.2 kj/mol, dG=−35.2 kj/mol and k₄=2.39E2.0 for reaction (7). For the specific case of FeBr₂ at 600° C. (and where m=2 and n=1.5): dH=−271 kj/mol, dG=−250 kj/mol and k₃=9.8E14 for reaction (6); and dH=69.4 kj/mol, dG=−5.3 kj/mol and k₄=2.06 for reaction (7). It is noteworthy that X₂, Y₂; H₂ and HX are in a gas phase.

The oxidative cleaning reaction (6) may be performed in any suitable manner. One suitable method for cleaning the organic residue includes heating the heater body and outer container to a desired temperature with an energy source; introducing oxygen into reactor 100; burning the organic residue with the heated gas to give an oxidized gas; and discharging the oxidized gas from the reactor. During the cleaning process, the inside temperature of reactor 100 is typically heated to at least 400° C. The gas supply used to clean reactor 100 is typically pressurized oxygen, and may be added to reactor 100 to a pressure in the range of approximately 1 to 20 psi, or, alternatively, to any other suitable pressure.

While cleaning the organic resides, the oxidative cleaning process also may convert the metal halide on the interior surfaces of the reacted-reactor to a metal oxide. In this case, the metal can be restored from the metal oxide by heating under a suitable reductive gas, such as hydrogen or a mixture of hydrogen with a diluent gas, as shown in reaction (7) above. Other reducing agents that can be used for the reductive reaction (7) include, but are not limited to, ammonium hypophosphite, hydrazine and borohydride. These reducing agents can be dispensed inside the reactor as an aqueous solution or as a pure liquid agent. Furthermore, where reactor 100 is made from a ceramic material, such as quartz, the reactor may be cleaned using oxidative plasma in conjunction with a plasma-cleaning device.

By comparing reactions (4), (5), (6), and (7) to reaction (2), one observes that the multi-reaction regeneration methods are kinetically more suitable for cleaning the reactor of this invention due to their high reaction constants than the single step regeneration methods. It is also noteworthy that an end point detector (e.g. a residual gas analyzer (“RGA”)) can be used to determine the completion of reactions (6) and (7) by monitoring the contents of the bromine (from reaction 6) and water (from reaction 7).

It will be appreciated that the above examples of reactor materials, cracking reactions and regeneration reactions are intended exemplify the principles disclosed herein, and are not intended to limit the scope of the invention in any manner. One skilled in the art will appreciate that the material selection criteria for reactor 100 can be easily applied to other metals, taking into account the chemical properties of the precursor material, reactive intermediate, and leaving groups.

In some embodiments, the individual components of reactor 100 (i.e. outer container 110, inlet section 112, outlet section 114 and heater body 114) are made entirely of the metal reactant. In other embodiments, the individual components of reactor 100 may be made of other materials, and the surfaces of the reactor that are exposed to the precursor flow are at least partially coated with the metal reactant. In these embodiments, the material from which the bulk of the reactor components are made may be referred to as a substrate that supports a film, layer or plating of the metal reactant. Examples of suitable substrate materials include, but are not limited to Ni and its alloys such as Monel and Inconel, Pt, Cr, Fe, and stainless steel. Nonmetallic materials can also be used to as substrate materials. Examples of suitable nonmetallic materials include, but are not limited to, quartz, sapphire or Pyrex glass, aluminum nitride, alumina carbide, aluminum oxide, surface fluorinated aluminum oxides, boron nitride, silicon nitride, and silicon carbide. The layer of metal reactant deposited over the substrate may also help to prevent contaminants from the substrate material from contaminating a growing polymer film.

Heater body 140 may be configured provides a sufficient surface area for reaction with the precursors to collide as they are transported through reactor 100. Although not wanting to be bound by theory, the reaction rate is proportional to the surface area under the same Tᵣ. In a preferred embodiment of the present invention, the volume of the reactive-reactor is less than 60 cm³, and the surface area of the heater body is at least 300 cm², preferably 500 cm².

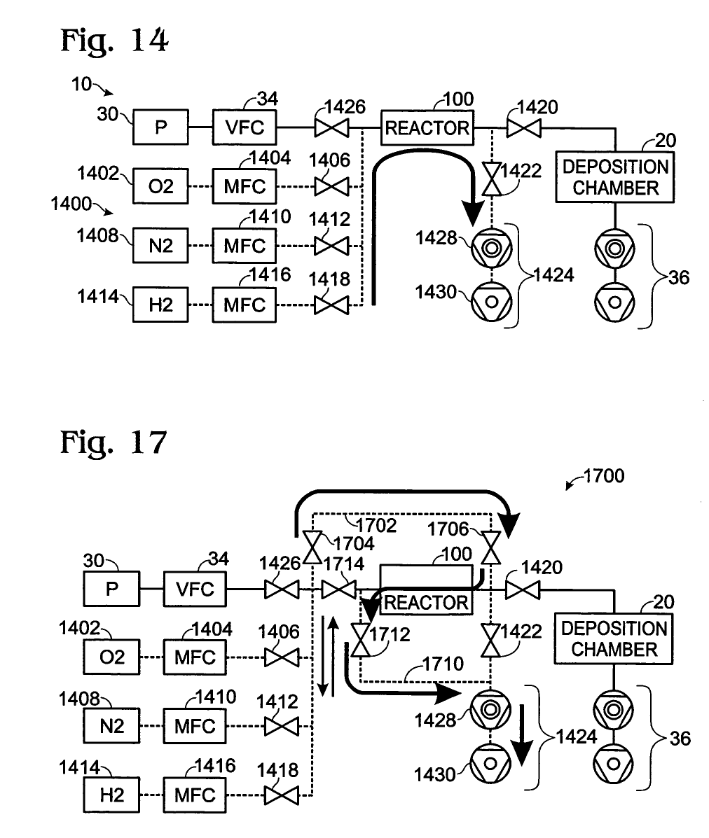

Deposition system 10 may include a system for periodically regenerating reactor 100. One embodiment of such a Reactor Regenerating System (RRS) is shown generally at 1400 in FIG. 14. Reactor regenerating system 1400 includes an oxidizing agent source (such as an oxygen source) 1402 connected to reactor 100 by a mass flow controller 1404 and a valve 1406, an inert purging gas source (such as a nitrogen source) 1408 connected to reactor 100 by a mass flow controller 1410 and a valve 1412, and a reducing gas source (such as a hydrogen source) 1414 connected to reactor 100 by a mass flow controller 1416 and a valve 1418. Also, downstream of reactor 100, a deposition chamber valve 1420 and a bypass valve 1422 allow outflow from reactor 100 to be directed either into deposition chamber 20 or into a waste disposal subsystem 1424. Waste disposal subsystem 1424 is depicted as including a high-vacuum pump 1428 and a backing pump 1430. Wastes pumped through waste disposal subsystem 1424 may be directed into a sewage storage tank (not shown) for storage, or into a scrubber (not shown) for burning. Furthermore, a precursor source valve 1426 allows selective isolation of precursor source 30 from the other components of reactor system 10 and reactor regenerating system 1400.

During normal use, valves 1406, 1412 and 1418 are closed, while valve 1426 is open. This allows a flow of the precursor to reach reactor 100. Furthermore, valve 1422 is closed, while valve 1420 is open. This allows a flow of reactive intermediates from reactor 100 to reach deposition chamber 20. This flow path is illustrated in FIG. 14 in solid lines.

Next, during an oxidative cleaning process, valves 1426, 1412 and 1418 are closed, while valve 1406 is opened. This allows the oxidative cleaning gas to flow into reactor 100. As described above, the oxidative cleaning gas may be introduced into reactor 100 at a pressure of, for example 1 to 20 psi, and the reactor may be heated to a temperature of greater than 400° C. to burn organic residues from the inside of the reactor. Valve 1424 may be closed during this process, such that the oxidative gas is trapped in reactor 100 during the oxidative cleaning process. In this case valve 1406 also may be closed after sufficient oxidative gas is introduced into reactor 100 but before commencing heating. Alternatively, valve 1424 may be opened during the cleaning process, and a continuous flow of oxidative cleaning gas may be directed through reactor 100 during the cleaning process. This flow path is illustrated in FIG. 14 in dashed lines.

After completing the oxidative cleaning process, reactor 100 may be purged with an inert purging gas, such as nitrogen, from inert purge gas source 1408. In this case, valves 1412 is opened, while 1406, 1418 and 1426 remain closed. Furthermore, valve 1420 is closed and valve 1422 is opened, directing the purge gas into waste disposal system 1424, as indicated by the dashed line path of FIG. 14. While nitrogen is depicted as the purging gas, any other suitable non-oxidizing gas, such as argon, may be used.

The oxidative cleaning process may oxidize the metal reactant within reactor 100. Furthermore, even where the oxidative cleaning process is not run, the metal reactant within reactor 100 may be fully reacted with leaving groups, and thus may require regeneration. Thus, after purging reactor 100 (or after the metal reactant is completely reacted with leaving groups), valve 1418 is opened, while valves 1412, 1406 and 1426 are closed. This introduces the reducing gas into reactor 100 for the regeneration process. After introducing the reducing gas into reactor 100, the reactor is heated to T_{rg} (or T_{d}). Waste products from the regeneration reaction are directed to waste disposal subsystem 1424 by opening valve 1422 and closing valve 1420, either during the reducing process, or upon the completion of the reducing process. After reducing, reactor 100 may again be purged with nitrogen (or other suitable inert gas) before being used again for reactive intermediate generation.

Any suitable gas mixtures, pressures and reactor temperatures may be used for the oxidative cleaning and regeneration processes. Some example conditions are as follows. For the oxidative cleaning process (reaction (7)), 1 to 5 psi of oxidative cleaning gas may be introduced from oxidative cleaning gas source 1402, and preferably from 5 to 20 psi of the gas. The reactor temperature may be at least 400° C., and preferably 600° C. to reduce the cleaning time. Besides oxygen, examples of other suitable oxidative cleaning gases include, but are not limited to, sulfur- and amino-containing compounds.

For the reductive regeneration process, one example of a suitable reducing gas for reducing gas source 1414 is 3-50% of hydrogen in an inert gas, such as nitrogen or argon. Alternatively, pure hydrogen, or mixtures of greater than 50% hydrogen with an inert gas, may also be used. The reducing gas mixture may be injected into reactor 100 to a pressure of 1 to 5 Torrs, or alternatively, 5 to 20 Torrs. For example, where nickel is the metal reactant and bromine is the leaving group, nickel bromide may be converted to nickel at 600° C. using 4% hydrogen in Argon for about 10 minutes under the gas pressure of 3 to 5 psi, or alternatively 5 to 20 psi.

Table II shows a summary of a suitable set of conditions for cleaning and regenerating a nickel metal reactant within an exemplary reactor 100 having a total interior volume of approximately 1400 cm³ and an interior surface area of approximately 1980 cm². The oxidation and regeneration reactions were performed at 650° C. The “fill time” is the amount of time taken to fill the reactor with the stated amount of gas, the “soak time” is how long the gas was held within the reactor before purging, and the “purge time” is how long the purging gas was flowed through the reactor.

TABLE II

| | | Nitrogen | |
|---|---|---|---|
| Parameter | Oxygen (O₂) | (N₂) | Hydrogen (H₂) |
| Fill Amount (scc) | 10-1000 | 200-1,000 | 20-1,200 |
| | 30-300 (preferred) | or more | 60-600 (preferred) |
| Fill Time (min) | 0.5-2.0 | N/A | 0.5-2.0 |
| Soak Time (min) | 1.0-5.0 | N/A | 1.0-5.0 |
| Purge Time (min) | N/A | 1.0-2.0 | N/A |

The amounts of oxidizing gas (e.g. oxygen) and reducing gas (e.g. hydrogen) used to clean the reactor may depend on the amount of reactive metal and the amount of deactivated reactive metal inside the reactor. The ranges of molar ratio of O₂/H₂/Ni and O₂/Precursor (“P”) ratio that are useful for these processes respectively include, but are not limited to, ratios from 1/1/0.02 to 1/20/0.02 and from 1/8/0.6 to 0.5/1. When the reactor is cleaned after deposition of every 5 to 7 wafers, the preferred cleaning recipes are CC4, CC5 & CC6 that have the O₂/H₂/Ni ratio ranges from 1/2/0.5 to 1/8/2.16 and the O₂/P ratio of about 0.5 to 1.9, as shown in Table III:

TABLE III

| | O/H/Ni | O₂/Precursor |
|---|---|---|
| Recipes | (Molar Ratios) | (Molar ratios) |
| CC4 | 1/1/0. 0.537 | 1.86 |
| CC6 | 1/8.01/2.16 | 0.47 |
| CC5 | 1/4.05/2.16 | 0.47 |

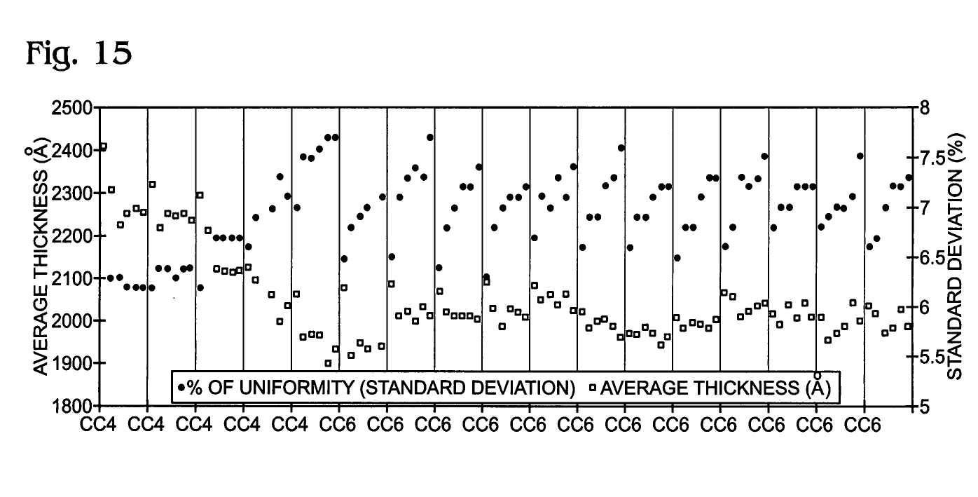

The effects of the cleaning recipe to the repeatability of reactor performance as can be evaluated by the wafer-to-wafer thickness uniformity of a film deposited using a cleaned and regenerated reactor. FIG. 15 shows a plot of the uniformity of thickness of low dielectric constant polymer films as a function of the cleaning process used to clean and regenerate reactor 100 before the film deposition. Each major division across the horizontal axis separates test results from individual wafers, and each data point within a between adjacent major divisions signifies the averaged polymer film thickness at a point on a wafer. The “CC4” and “CC6” labels indicate which cleaning process of Table III was used to clean the reactor before that film deposition. As shown in FIG. 15, CC6 resulted in better wafer-to-wafer thickness uniformity. This indicates that the CC6 cleaning process shown in Table III may help to maintain the consistency of performance of reactor 100 over time better than the CC4 cleaning process.

In order to reduce the level of metallic contaminants within reactor 100 to a suitably low level for semiconductor device fabrication, (less than 5×10¹⁰ atoms/cm² of a metal contaminant), reactor 100 may undergo various cleaning steps and high-purity plating steps during manufacturing of the reactor. The term “pre-cleaned reactor” is used herein to refer to a reactor that has been assembled and pre-cleaned in such a manner as to avoid contamination with undesirable metal contaminants such as alkaline and alkali metals. This pre-clean step may be particularly useful when the reactor is constructed from stainless steel and the inner surfaces of the outer container 110 and the outer surfaces of heater body 140 are coated with Ni by electrolytic or electro-less plating methods.

One example of a suitable pre-cleaning and manufacturing process for reactor 100 includes the following: (1) pre-cleaning of the reactor parts before coating of the metal reactant on the parts; (2) coating the metal reactant onto the reactor parts with an alkaline-metal-free composition; (3) post-plating cleaning of the interior surfaces of the reactor; (4) assembling the reactor from the coated parts without cracking the coating on the components and without introducing metal contaminants into the reactor; and (5) preconditioning the reactor at high temperature and under inert gas purge. Details on these individual steps are as follows.

First, pre-cleaning the reactor parts before coating the parts with the metal reactants may help the metal reactant to bond more strongly to the underlying reactor parts, and also may help to remove contaminants from the reactor parts before coating the parts with the metal reactant. The pre-cleaning process may include: (a) degreasing the metal-reactant-substrate surface with a degreasing agent to form a degreased reactor substrate surfaces; (b) alkaline-cleaning the degreased metal-reactant-substrate surface with an alkaline agent to form an alkaline-metal-treated reactor substrate surface; (c) hot-rinsing the alkaline-metal-treated reactor substrate surface with a hot-rinsing agent to form a hot-rinsed reactor substrate surface; (d) acid-pickling the hot-rinsed reactor substrate surface with an acid pickling agent to form an acid-pickled reactor substrate surface; (e) striking the acid-pickled reactor substrate surface with a striking agent to form a struck reactor substrate surface; (f) cold-rinsing the struck reactor substrate surface with a cold-rinsing agent to form a cold-rinsed reactor substrate surface; (g) repeating steps (a)-(f) for the cold-rinsed-metal-reactant-substrate-surface; and (h) final rinsing the repeated-cold-rinsed-metal-reactant-substrate-surface with a final cold rinse agent at a seventh temperature to form a pre-cleaned reactor substrate surface.

The individual steps of the pre-cleaning process may be performed with any suitable degreasing agents, alkaline-cleaning agents, hot-rinsing agents, acid-pickling agents, cold rinsing agents, and final rinsing agents. Examples of suitable agents include, but are not limited to, the following: the degreasing agent may be chloroform (“CHCl₃”); the alkaline-cleaning agent may be NaOH; the hot-rinsing agent may be or deionized H₂O; the acid-pickling agent may be 1:1 HCl; the striking agent may be nickel chloride; the cold rinsing agent may be distilled or deionized H₂O; and the final rinsing agent may be isopropyl alcohol.

Likewise, the individual steps of the pre-cleaning process may be performed at any suitable temperature or temperatures, and for any suitable duration or durations of time. In the specific case where the metal reactant is nickel and is applied via electro-less plating, examples of suitable pre-treatments are found in W. Riedel, “Electro-less nickel Plating”, ASM International, Finishing Publication Ltd. 1998 2^{nd} Edition, Chapter 9. Furthermore, one specific embodiment of a pre-treatment for a reactor made of 316 stainless steel before the electro-less plating of nickel onto the reactor is shown in Table IV.

TABLE IV

| | | T | Time |
|---|---|---|---|
| Pre-treatment step | Chemical | (° C.) | (min) |
| 1. Degrease | CHCl₃ | 25 | 5 |
| 2. Alkaline Cleaning | NaOH | 80 | 5 |
| 3. Hot Rinse | H2O | 65 | 5 |
| 4. Acid Pickling | 1:1HCl | 25 | 0.5 |
| 5. Striking | Nickel chloride | 25 | 5 |
| 6. Cold rinse | H2O | 25 | 5 |
| 7. Repeat steps (2-6), 3 | | | |
| times | | | |
| 8. Final Cold Rinse | IPA | 25 | 5 |

After pre-cleaning the reactor parts, the reactor parts are next coated with the metal reactant. Any suitable method may be used to coat the reactor parts with the metal reactant. Examples of suitable methods include, but are not limited to, dip coating, electro-less plating, electrolytic plating, spray coating, vapor deposition, sputtering and combinations thereof.

In one specific embodiment, a first layer of metal reactant is deposited via an electro-less process, and a second layer of the metal reactant is deposited on the first layer of metal reactant via an electrolytic process. In this specific embodiment, the metal reactants are generally noble metals (e.g. Au or Pt), but may be any other suitable material. The interior surfaces may have any suitable thickness, and are typically thin coatings sufficiently thick to provide pinhole free barrier for the underlying vacuum vessel and heater body bulk materials.

In another embodiment, outer container 110, heater body 140, or both are constructed from 316 stainless steel or titanium. These parts are coated with a non-alkaline-metal-containing (“NAMC”) composition for electro-less plating. The NAMC is formed by mixing: an ionic metal source; a reducing agent; a complexing agent; and a buffer agent. The ionic metal source may be nickel sulfate or nickel acetate; the reducing agent may include a hypophosphite or a boron-nitrogen composition, ammonium hypophosphite, trimethylamine hypophosphite, polyethyleneimmine hypophosphite, dimethylamine borohydride, diethylamine borohydride, or hydrazine borohydride; the complexing agent may include citric acid, hydroxycarboxylic acid, amino-acetic acid, glycolic acid, or trimethylamine-C₆H₄O₇*2H₂O; and the buffer agent includes ammonia, or boric acid.

Other examples of suitable coating materials are electro-less Ni, Ni—P or Ni—B (i.e. nickel doped with phosphorus or boron), electro-plated Ni, and a combination of electro-less plated Ni covered with electrolytic Ni, as shown in the following Table V:

TABLE V

| Vessel and Heater | | | | |
|---|---|---|---|---|
| body Materials | SST 316 | SST 316 | SST 316 | SST 316 |
| Metal Reactant | Electro- | Electrolytic | E/EL Ni—P | E/EL Ni—B |
| Or | less Ni—P | Ni | (8% P) | (2% B) |
| Interior Surfaces | (8% P) | | | |
| Thickness of | 25 | 15 | (7/18) | (7/18) |
| Metal Reactant | | | | |
| (μm) | | | | |

Furthermore, Riedel has reviewed many non-alkaline-metal-containing compositions useful for this invention in the Chapter 3 of W. Riedel, “Electro-less nickel Plating,” ASM International, Finishing Publication Ltd. 1998 2^{nd} Edition). Table VI summarizes some useful NAMC compositions for the electro-less plating of Ni.

TABLE VI

| Electro-less Plating | | | |
|---|---|---|---|
| Solution Components | | | Example Materials |
| 1. | Ni ion source | | Ni sulfate, nickel acetate |
| 2. | Reducing Agent | | |
| | a. | Hypophosphite | Ammonium Hypophosphite, |
| | | | (Trimethylamine)H₂PO₂, Polyethyleneimine, |
| | | | Hypophosphite |
| | b. | Boron-Nitrogen | Dimethylamine Borohydride, Diethylamine |
| | | | Borohydride, Hydrazine Borohydride. |

| | | |
|---|---|---|
| 3. | Complexant | Citric acids, Hydroxycarboxylic acids, |
| | | Amino-acetic acid, glycolic acid. |
| | | (Trimethylamine)₃C₆H₄O₇•2H₂O |
| 4. | PH Buffer | Ammonia, Boric Acid |

To ensure uniform plating, parts included for the assembly of the reactor may be plated separately, and then assembled afterwards. For instance, the vacuum vessel (130) and the inside heater body (120) can be plated separately, and later welded together. Care may be taken not to crack the NAMC coat on the components and not to introduce metal contaminants into the reactor during assembly.

Because the welding process creates metal particulates that may remain inside the reactor and cause metal contamination during deposition of thin films, the number of welds used may be kept relatively small, unless pre-cleaning was done very thoroughly. Precautions may be taken to ensure that the reactor assembly process does not crack the metal reactant coatings such as Ni on the surfaces inside the reactor. In addition, the welding process may be done without flux, solder or other chemicals to avoid introducing metal contamination in the reactor.

Next, the assembled reactor 100 may undergo a post-assembly cleaning process. The primary function of the post-assembly cleaning process is to remove adherents including metallic particulates and other inorganic compounds, including but not limited to sodium, calcium or potassium compounds. Any suitable cleaning method may be used. Suitable methods include those that remove contaminants and debris from the welding process, and/or do not introduce metallic contaminants into the reactor. One example of a suitable post-assembly and post-coating cleaning process is an ultrasound cleaning process. Ultrasound cleaning processes are typically performed inside an ultrasonic tank having an ultrasonic cleaning solution at an ultrasonic cleaning frequency, and at an ultrasonic-cleaning temperature.

A suitable ultrasonic cleaning process for assembled reactor 100 may utilize, for example, an ultrasonic cleaning solution of deionized water, a detergent, organic solvents, and/or combinations thereof. Additionally, suitable processes include, but are not limited to, those that utilize an ultrasonic cleaning-frequency of about 42 KHz, and an ultrasonic-cleaning temperature of about 30° C. to about 35° C. The post-coat, post-assembly cleaning process may also include rinsing the post-coat-cleaned reactive reactor with distilled water.

The ultrasonic cleaning solution may also be a weak aqueous acid solution, such as a metal-free acetic acid solution. If a weak acid solution is employed, then the reactor may be further rinsed with distilled water and then isopropyl alcohol. Furthermore, if a detergent solution is used as an ultrasonic cleaning solution, the reactor may be rinsed with distilled or deionized water after the ultrasonic cleaning process to remove any remaining ions adsorbed onto the interior surfaces of the reactor. After the post cleaning, the reactor may be bagged in a clean room, for example, a class 100 clean room, for shipping or storage.

Table VII shows the contaminants on a wafer in units of 10¹⁰ atoms/cm², following ultrasonic cleaning and deposition. Unless indicated otherwise, the ultrasonic cleanings of these samples were performed at 42 KHz and 30-35° C. in distilled or deionized water.

TABLE VII

| | K | Ca | Ti | Cr | Mn | Fe | Co | Ni | Cu | Zn |
|---|---|---|---|---|---|---|---|---|---|---|
| Control: | | | | | | | | | | |
| Un- | | | | | | | | | | |
| cleaned⁽²⁾ | | | | | | | | | | |
| Center | 40 | 30 | 63 ± 5 | 1900 ± 110 | 1320 ± 80 | 7300 ± 400 | I | 34000 ± 2000 | I | 510 ± 30 |
| 0, 80 | 35 | 20 | 10 ± 1.9 | 920 ± 60 | 640 ± 40 | 3800 ± 200 | I | 25500 ± 1500 | I | 235 ± 14 |
| 0, −80 | 39 | 27 | 20 ± 2 | 1730 ± 100 | 1300 ± 80 | 4900 ± 300 | I | 28000 ± 1700 | I | 380 ± 20 |
| After | | | | | | | | | | |
| Ultrasonic | | | | | | | | | | |
| in DW: | | | | | | | | | | |
| Bare Si | | | | | | | | | | |
| wafer | | | | | | | | | | |
| Center | <5 | <5 | <1.4 | <0.7 | <0.6 | <0.5 | <0.4 | <0.4 | <0.4 | <0.5 |
| 0, 80 | <5 | <5 | <2.5* | <0.8 | <0.7 | 4.3 ± 0.4 | <0.4 | <0.4 | 2.4 ± 0.3 | 1.2 ± 0.3 |
| 0, −80 | <5 | <5 | <1.5 | 3.7 ± 0.5 | <0.6 | 3.5 ± 0.4 | <0.4 | <0.4 | 0.6 ± 0.2 | 2.1 ± 0.3 |
| (1^{st} wafer) | | | | | | | | | | |
| deposition | | | | | | | | | | |
| Center | <5 | <5 | <1.4 | <0.8 | <0.6 | 1.8 ± 0.4 | <0.4 | 6.2 ± 0.6 | <1.7* | 3.9 ± 0.5 |
| 0, 80 | <5 | <10* | <1.6 | <0.9 | <0.7 | 2.1 ± 0.4 | <0.5 | <0.6 | 2.2 ± 0.4 | 7 ± 0.7 |
| 0, −80 | <5 | <10* | 3.4 ± 1.2 | <1.1 | <0.9 | 11 ± 1 | <0.6 | 3 ± 0.5 | 6 ± 0.6 | 44 ± 3 |
| (6^{th} | | | | | | | | | | |
| wafer) | | | | | | | | | | |
| deposition | | | | | | | | | | |
| Center | <5 | <5 | <1.4 | <0.8 | <0.6 | <1.0* | <0.5 | <0.8 | <0.7 | 2.3 ± 0.5 |
| 0, 80 | <5 | <5 | <2 | <0.9 | <0.7 | 2.1 ± 0.4 | <0.5 | <0.6 | 4 ± 0.4 | 4.2 ± 0.5 |
| 0, −80 | <5 | <5 | <1.5 | <1.2 | <0.7 | 2.8 ± 0.4 | <0.5 | <0.6 | 2.6 ± 0.4 | <2* |
| (10^{th} | | | | | | | | | | |
| wafer) | | | | | | | | | | |
| deposition | | | | | | | | | | |
| Center | <5 | <5 | <1.5 | <0.8 | <0.7 | <0.6* | <0.5 | <0.6 | <1.0 | 2.8 ± 0.5 |
| 0, 80 | <5 | <5 | <1.5 | <0.9 | <0.7 | 1.9 ± 0.4 | <0.5 | 0.9 ± 0.3 | 3 ± 0.4 | 3.7 ± 0.5 |
| 0, −80 | <5 | <5 | <1.6 | <0.9 | <0.7 | 1.8 ± 0.4 | <0.5 | <0.5 | 2.5 ± 0.4 | 4.3 ± 0.5 |

Footnotes: (*) may be present near detection limits;
(²) when above ultrasonic cleaning was performed inside isopropyl alcohol, the K and Ca concentrations were not lowered;
(³) re-generation of reactor was performed between 5^{th} and 6^{th} wafers.

After the post-assembly cleaning process, the assembled, cleaned reactor 100 may be pre-heated under inert conditions before the reactor is used for a thin film deposition process. The pre-heating process may help to purge off any remaining ionic contaminants on the interior surface of reactor 100. Pre-heating the reactor may include heating the reactor under inert condition to high temperature, and optionally purging the reactor with an inert gas, such as nitrogen. This may further help reduce ionic contaminant concentrations to acceptable levels for IC fabrication. Table VIII shows the results of determinations of contaminant concentrations on the surface of wafers after processing by (1) an unpurged and un-preheated reactor, (2) after being heated to 650° C. and purged with nitrogen for one hour, (3) after being heated to 650° C. and purged with nitrogen for three hours, (4) after 20 depositions (while regenerating every five depositions), and (5) after 26 depositions (while regenerating every five depositions). It is noted that more mobile ions and alkaline/alkali metal contaminants such as K, Ca, Na and their compounds may be removed by purging with an inert gas at temperatures above 350° C., whereas heavy metals and some other transition metals such as Ti may require temperatures of up to 600 to 650° C.

TABLE VIII

| Test | | | | | | | | | |
|---|---|---|---|---|---|---|---|---|---|
| positions | K | Ca | Ti | Cr | Mn | Fe | Ni | Cu | Zn |
| UN- | | | | | | | | | |
| PURGED | | | | | | | | | |
| Reactor | | | | | | | | | |
| Center | 63 ± 5 | 1900 ± 110 | 1320 ± 80 | 7300 ± 400 | I | 34000 ± 2000 | I | 510 ± 30 | 4600 ± 300 |
| position | | | | | | | | | |
| 80 mm | 10 ± 1.9 | 920 ± 60 | 640 ± 40 | 3800 ± 200 | I | 25500 ± 1500 | I | 235 ± 14 | 3600 ± 200 |
| from | | | | | | | | | |
| center | | | | | | | | | |
| 80 mm “” | 20 ± 2 | 1730 ± 100 | 1300 ± 80 | 4900 ± 300 | I | 28000 ± 1700 | I | 380 ± 20 | 4100 ± 200 |
| After 650 | | | | | | | | | |
| ° C., l hr/N₂ | | | | | | | | | |
| Center | <5 | <5 | 6 ± 0.9 | <0.7 | <0.6* | 9 ± 0.7 | 50 ± 3 | <0.5 | <0.6 |
| position | | | | | | | | | |
| 0, 80 | <5 | <5 | <1.5 | <0.8 | <0.6 | 4.2 ± 0.4 | 16.8 ± 1.1 | <0.4 | <0.6 |
| 0, −80 | <5 | <5 | <1.5 | 1.8 ± 0.4 | <0.6 | 2.9 ± 0.4 | 3.8 ± 0.4 | 0.6 ± 0.2 | <0.7 |
| After 650 | | | | | | | | | |
| ° C., 3 hr/N₂ | | | | | | | | | |
| Center | <5 | <5 | <1.4 | <0.7 | <0.6 | 0.6 ± 0.3 | 34 ± 2 | <0.5 | <0.6 |
| 0, 80 | <5 | <5 | <1.6 | <0.9 | <0.7 | 4.4 ± 0.5 | 0.6 ± 0.2 | <0.5 | 7 ± 0.5 |
| 0, −80 | <5 | <5 | <2* | 1.5 ± 0.4 | <0.7 | 5 ± 0.5 | 0.9 ± 0.2 | 3.4 ± 0.3 | 1.2 ± 0.3 |
| 20^{th} wafer | | | | | | | | | |
| deposition | | | | | | | | | |
| Center | <5 | <5 | <1.4 | <0.8 | <0.7 | 0.8 ± 0.3 | <0.5 | 1.8 ± 0.3 | 3.7 ± 0.5 |
| 0, 80 | <5 | <5 | <1.6 | <0.9 | <0.7 | 1.9 ± 0.4 | <0.8* | 2.7 ± 0.4 | 2.6 ± 0.5 |
| 0, −80 | <5 | <5 | <1.6 | <0.9 | <0.7 | 2.6 ± 0.4 | <0.6 | 2 ± 0.4 | 2.4 ± 0.5 |
| 26^{th} wafer | | | | | | | | | |
| deposition | | | | | | | | | |
| Center | <7 | <5 | <2.6 | <1.3 | <1.1 | 1.0 ± 0.5 | <1.0* | 3.6 ± 0.5 | 3.1 ± 0.7 |
| 0, 80 | <5 | <5 | <2 | <0.9 | <0.7 | 1.5 ± 0.4 | <0.6 | 3 ± 0.4 | 2.9 ± 0.5 |
| 0, −80 | <5 | <5 | <1.6 | <0.9 | <0.7 | 1.8 ± 0.4 | <0.6 | 3.2 ± 0.4 | 3.5 ± 0.5 |

Footnotes:
Reactor was re-generated after every 5 wafers of film deposition.
Units are 10¹⁰ atoms/cm².

Pre-heating can alternatively comprise purging the pre-clean-reactive-reactor at a high temperature with an inert gas under vacuum, wherein the vacuum less than 100 mTorrs, preferably 20 mTorrs, at a temperature of at least 450° C. The inert gas comprises nitrogen or 3% of hydrogen in nitrogen. After pre-heating, the pre-heated reactor 100 may then be bagged in a clean room environment if desired.

Repeated depositions of low dielectric constant polymer films using reactor 100 also may cause organic deposits to build within the outlet of the reactor. These organic deposits may accumulate to such an extent as to impede the diffusion of intermediates out of reactor 100. This may, in turn, change the residence time of the precursors within the reactor, and thus may impair the proper functioning of the reactor over longer periods of time. Thus, reactor 100 may be provided with an outlet cleaning system to facilitate the periodic removal of the organic deposits from the outlet of the reactor, and thus to help extend the lifetime of the reactor.

FIG. 16 shows, generally at 1600, an embodiment of a reactor having an outlet cleaning system 1610 associated with the outlet 1602 of the reactor. Outlet 1602 includes an outlet tube 1604, and a flange 1606 for connecting the reactor to a gate valve that leads to a deposition chamber. Outlet cleaning system 1610 is positioned adjacent outlet tube 1604, and is configured to provide sufficient energy to the outlet tube to oxidize organic residues located within the outlet.

The type of energy provided by outlet cleaning system 1610 may vary depending upon the material of which outlet tube 1604 is made. As a first example, outlet tube 1604 may be made from quartz. In this case, ultraviolet radiation may be used in the presence of oxygen to decompose the organic deposits within the outlet. Ultraviolet radiation of any suitable wavelength may be used, including but not limited to ultraviolet radiation having a wavelength of 200 nm or less. The ultraviolet radiation source used to decompose the organic residues may be permanently attached to reactor 1600, or may be a portable unit that is removably attachable to outlet tube 1604 for cleaning processes.

As a second example, outlet tube 1604 may be made from a ceramic material such as silicon carbide. In this case, a plasma can be used to degrade and remove the organic deposits in the outlet tube of the reactor. Oxidative plasmas may be particularly useful for this process. Either a permanently attached plasma cleaning tool, or a detachable or portable plasma cleaning tool, may be used to clean outlet tube 1604. The plasma cleaning may be performed at any suitable frequency and power levels, including frequencies around 13.56 MHz and power levels from 10-2000 W.

Likewise, the application of microwave radiation in the presence of oxygen may also be used to clean outlet tube 1604 made of ceramics such as silicon carbide and quartz. Various organic residues may absorb microwaves directly, and may thus get hot enough to react with oxygen. Furthermore, silicon carbide and other ceramics also may absorb microwave energy and heat up, thus contributing to the heating of the organic residues. Microwave radiation of any suitable frequency may be used. Examples include, but are not limited to, microwave radiation with frequencies of approximately 2.4 GHz, and at power levels of between approximately 200 and 1000 W. Such a process may be able to remove organic deposits within 0.5 to 3 minutes depending on the energy of the microwave and amounts of oxygen or air presence inside outlet tube 1604.

Furthermore, outlet tube 1604 may be cleaned via resistive heating in the presence of oxygen. For example, outlet tube 1604 may contain embedded resistive heating filaments, or such filaments may be positioned on the outside of the outlet tube. Oxidative decomposition of organic deposits within outlet tube 1604 may occur when the temperature is over 400° C. To accelerate the decomposition process and reduce the cleaning time, the outlet tube may be heated to 500-600° C.

Additionally, ozone may be used as an oxidizing agent, instead of oxygen, for any of the above cleaning processes. When ozone is used, the temperature of the organic residues within outlet tube 1604 needs only to be heated to a temperature between approximately 50 and 300° C., and preferably between approximately 150 and 200° C. This may help to prevent overheating flange 1606. The ozone can be supplied using a commercially available ozone generator, or by generation of ozone inside the outlet tube of the reactor using UV with wavelength ranging from 190 to 220 nm.

It will be appreciated that outlet cleaning system 1610 may be used with any suitable reactor, whether the reactor interior includes a metal reactant (as described above), or an inert interior. Examples of inert materials that may be used to construct the reactor include, but are not limited to, quartz, sapphire or Pyrex glass, and ceramic materials such as alumina carbide, Al₂O₃, surface fluorinated Al₂O₃, silicon carbide, and silicon nitride.

The heater body may also be constructed from these ceramic materials. Silicon carbide has been tested as a heater body and/or as an outer container for a reactor, and has been found to be totally inert to bromine leaving groups and oxygen used in regenerating metal reactants within the reactor. However, it may be difficult to fabricate these parts from solid silicon carbide. Thus, the parts may be fabricated from graphite or a Chemical Vapor Reacted-SiC (CVR-SiC) process (in which SiC is formed by reacting graphite carbon with vapor-phase SiO2 at 1200 C), and then a CVD-deposited SiC layer can be coated over the CVR-SiC. This is because the CVR-SiC (generated by reacting graphite with SiO₂) may be porous, and the CVD-deposited SiC layer may seal these pores. This process is described in “Properties and Characteristics of Silicon Carbide” edited by A. H. Rashed, available from POCO Graphite Inc. (www.poco.com). In another specific embodiment, the outer container may be manufactured from quartz, and the heater body may be manufactured from (or coated with) silicon carbide. Quartz is transparent to infrared radiation, and thus can pass infrared radiation emitted by an infrared heater located outside of the outer container. Furthermore, silicon carbide is a very effective black body for absorbing and radiating infrared radiation, and it is resistant to oxygen and bromine up to 1000° C.

Furthermore, in some applications, it may be desired to form the outer container and heater body of reactor 1600 from a material that is reactive toward a leaving group (for example, a “metal reactant” as described above), but to passivate the reactivity of the material toward the leaving group. For example, it may be desired to utilize a resistive heater to heat the outer container, in which case it may be desirable to form the outer container from a material having a high thermal conductivity, such as a metal. Where the metal is reactive toward the leaving group and it is desired to passivate the metal, the metal may be coated with an inert material, such as silicon carbide, to prevent reactions between the leaving group and the outer container and/or heater body. Due to the large temperature differences to which the components of reactor 1600 are exposed, the coefficients of thermal expansion of the passivating material and the underlying metal may be matched as closely as possible to prevent cracking of the passivating layer caused by mismatched coefficients of expansion. Table IX below lists the coefficients of thermal expansion of silicon carbide and some possible heater body and outer container materials.

TABLE IX

| Material | CTE (/ppm) @ 20 C. |
|---|---|
| Quartz | 0.6 |
| SiC | 2-4.5 |
| W | 4.5 |
| Ti | 5.1 |
| Ta | 7 |
| Cr | 8.2 |
| Mo | 4.8 |
| Graphite | 8.39 |
| Pt | 8.5 |
| Fe | 10.6 |
| Ni | 13 |
| Au | 14 |
| SS 316 | 17.5 |
| Al | 23 |

As described above, outlet tube 1604, the outer container of the reactor, and flange 1606 may be made from the same material or materials, or from different materials. Table X below examines several potential combinations of materials for the reactor body, outer container, outlet tube and flange of the reactor. Two metals (nickel and stainless steel) and two ceramics (silicon carbide and quartz) are used in these combinations. Where nickel is listed as an example material, this signifies either pure nickel, or nickel coated over another substrate, such as iron. Also, it is indicated in the “Interface Solution” columns where two parts may be difficult to join together in a clean and effective manner.

TABLE X

| | 1. | 2. | 2-3 | 3. | 3-4 | |
|---|---|---|---|---|---|---|
| Example | Heater | Outer | Interface | Reactor | Interface | |
| No. | Body | Container | Solution | Exit | Solution | 4. Flange |
| 1 | Ni | Ni | yes | a. SiC | a. yes | a. Ni |
| | | | | b. Quartz | b. yes | b. Stainless Steel |
| 2 | Ni | Quartz | a. difficult | a. SiC | a. yes | a. Ni |
| | | | b. yes | b. Quartz | b. yes | b. Stainless Steel |
| 3 | SiC | Ni | a. yes | a. SiC | a. yes | a. Ni |
| | | | b. difficult | b. Quartz | b. yes | b. Stainless Steel |
| 4 | SiC | Quartz | a. difficult | a. SiC | a. yes | a. Ni |
| | | | b. yes | b. Quartz | b. yes | b. Stainless Steel |
| 5 | SiC | SiC | a. yes | a. SiC | a. yes | al. Ni |
| | | | b. difficult | b. Quartz | b. yes | b. Stainless Steel |

During the outlet cleaning process, oxygen (or other oxidant) may be run through the reactor either in the forward direction (i.e. in the direction that precursors and reactive intermediates flow during reactor use), or may be run through the reactor in a reverse direction. FIG. 17 shows the deposition system of FIG. 14 equipped with a reverse flow bypass system 1700 to allow reverse flow cleaning and purging processes to be performed. Reverse flow bypass system 1700 includes a first bypass line 1702 that leads from gas sources 1402, 1408 and 1414 into the outlet of reactor 100. First bypass line 1702 includes a first valve 1704 and a second valve 1706 for controlling access to the first bypass line at each end of reactor 100.

Reverse flow bypass system 1700 also includes a second bypass line 1710 for directing a flow of gas leaving the reactor inlet into pumping system 1424 for waste disposal. A valve 1712 positioned on second bypass line 1710 allows control of gas flow through the second bypass line, and a valve 1714 positioned upstream of reactor 100 prevents gas from flowing directly from the gas sources into second the second bypass line.

During normal operation, valves 1406, 1412, 1418, 1704, 1706, 1710 and 1422 are closed, while the other valves are opened. This allows precursor to flow into reactor 100, and allows reactive intermediates to flow from the reactor into deposition chamber 20. On the other hand, during a cleaning, regeneration or purging process, valves 1426, 1714, 1420 and 1422 are closed, while the other valves (including at least one of the gas source valves 1406, 1412, 1418) are opened. This causes gas to flow first through first bypass line 1702, then through reactor 100 in the reverse direction, and then through second bypass line 1710 for discharge through pumping system 1424. Reverse flow bypass system 1700 may also be used to cause gases to flow through reactor 100 in a reverse direction during a purging or regeneration process, if desired.

Although the present disclosure includes specific embodiments of various composite dielectric films, methods of forming the films, and systems for forming the films, specific embodiments are not to be considered in a limiting sense, because numerous variations are possible. The subject matter of the present disclosure includes all novel and nonobvious combinations and subcombinations of the various films, processing systems, processing methods and other elements, features, functions, and/or properties disclosed herein. For example, the above example systems are for a single deposition chamber with a single reactor; however, it should be appreciated by those of ordinary skill in the art, in view of this disclosure, that other embodiments may incorporate the concepts, methods, precursors, polymers, films, and devices of the above description and examples. The description and examples contained herein are not intended to limit the scope of the invention, but are included for illustration purposes only. It is to be understood that other embodiments of the invention can be developed and fall within the spirit and scope of the invention and claims. For example, all of the above discussions assume a single reactor per one deposition chamber, however, those who are skillful in tool designs can easily apply the above principles to make a larger reactor for industrial cluster tools that have multi-deposition chambers.

The following claims particularly point out certain combinations and subcombinations regarded as novel and nonobvious. These claims may refer to “an” element or “a first” element or the equivalent thereof. Such claims should be understood to include incorporation of one or more such elements, neither requiring nor excluding two or more such elements. Other combinations and subcombinations of features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

What is claimed is:

1. A method of producing a reactive intermediate having at least two free radicals from a precursor having a general formula of Xₘ—Ar—(CZ′Z″Y)ₙ via a reactor made at least partially of a material M that is reactive with the precursor to produce at least one of MₐY_{b} and M_{c}X_{d}, wherein Ar is an aromatic moiety, the method comprising:
heating the reactor;
introducing a flow of precursor into the reactor;
contacting the precursor with the material M to form the reactive intermediate and at least one of MₐY_{b} and M_{c}X_{d}; and
reducing MₐY_{b} to M and a compound comprising Y and/or reducing M_{c}X_{d} to M and a compound comprising X after forming the reactive intermediate and the at least one of MₐY_{b} and M_{c}X_{d}.

2. The method of claim 1, wherein X and Y are leaving groups each comprising one or more of ketene and carboxyl groups, bromine, iodine, —NR₂, —N⁺R₃, —SR, —SO₂R, —OR, ═N⁺═N—, —C(O)N₂, and —OCF—CF₃, wherein R is an alkyl or aromatic group.

3. The method of claim 1, wherein Y is Br, and wherein m=0 and n=2.

4. The method of claim 1, wherein M comprises one or more comprises one or more of chromium, nickel, titanium, gold, iron, platinum, chromium, silver, cobalt and tungsten.

5. The method of claim 4, wherein Z′ is F, Z″ is F, M is nickel and Y is Br.

6. The method of claim 1, wherein heating the reactor comprises heating the reactor to a temperature lower than a temperature at which Y is dissociated from the precursor in the absence of M.

7. The method of claim 1, wherein introducing a flow of precursor into the reactor comprises introducing a flow of 1-6 sccm of precursor into the reactor.

8. The method of claim 1, wherein heating the reactor comprises heating a heater body within the reactor substantially exclusively via radiative heating.

9. The method of claim 1, wherein heating the reactor comprises heating an interior surface of the reactor to an average temperature equal to or less than 700 degrees Celsius.

10. The method of claim 9, wherein the average temperature equal to or less than 700 degrees Celsius has a variation of equal to or less than +/−20 degrees Celsius across the interior surface of the reactor.

11. The method of claim 1, wherein Ar is a phenyl or a partially or fully substitute phenyl.

12. The method of claim 1, wherein reducing MₐY_{b} to M and a compound comprising Y comprises reacting MₐY_{b} with hydrogen.

13. The method of claim 12, wherein M is nickel and Y is bromine, and wherein reducing MₐY_{b} comprises reacting NiBr₂ with hydrogen to form Ni and HBr.

14. The method of claim 1, wherein reducing MₐY_{b} comprises first converting MₐY_{b} to an oxide, and then reducing the oxide.

15. The method of claim 14, wherein M is nickel and Y is bromine, and wherein reducing MₐY_{b} comprises converting NiBr₂ to NiO, and then converting NiO to nickel and H₂O.

16. The method of claim 1, wherein reducing MₐY_{b} to M comprises heating MₐY_{b} to a temperature at which MₐY_{b} decomposes into. M and Y.

17. A method of producing a reactive intermediate of the general formula Ar—(CF₂*)₂ from a precursor having a general formula of Ar—(CF₂Br)₂ via a reactor made at least partially of a material M that is reactive with the precursor to produce MBr_{b}, wherein Ar is an aromatic moiety and wherein * is a free radical, the method comprising:
heating the reactor;
introducing a flow of precursor into the reactor;
contacting the precursor with the material M to form the reactive intermediate and MBr_{b}; and
reducing MBr_{b} to M and a compound comprising Br after forming MBr_{b} and the reactive intermediate.

18. The method of claim 17, wherein M comprises one or more of chromium, nickel, titanium, gold, iron, platinum, chromium, silver, cobalt and tungsten.

19. The method of claim 17, wherein heating the precursor comprises heating the precursor to a temperature lower than a temperature at which Br is dissociated from the precursor in the absence of M.

20. The method of claim 17, wherein introducing a flow of precursor into the reactor comprises introducing a flow of 1-6 sccm of precursor into the reactor.

21. The method of claim 17, wherein heating the reactor comprises heating a heater body within the reactor substantially exclusively via radiative heating.

22. The method of claim 17, wherein heating the reactor comprises heating an interior surface of the reactor to an average temperature equal to or less than 700 degrees Celsius.

23. The method of claim 22, wherein the average temperature equal to or less than 700 degrees Celsius has a variation equal to or less than +/−20 degrees Celsius across the interior surface of the reactor.

24. The method of claim 17, wherein Ar is a phenyl or partially or fully substituted phenyl.

25. The method of claim 17, wherein reducing MBr_{b} to M and a compound comprising Br comprises reacting MBr_{b} with hydrogen.

26. The method of claim 25, wherein M is nickel, and wherein reducing MBr_{b} comprises reacting NiBr₂ with hydrogen to form Ni and HBr.

27. The method of claim 17, wherein reducing MBr_{b} comprises first converting MBr_{b} to an oxide, and then reducing the oxide.

28. The method of claim 27, wherein M is nickel, and wherein reducing converting MBr_{b} to an oxide and then reducing the oxide comprises converting NiBr₂ to NiO, and then converting NiO to nickel and H₂O.

29. The method of claim 17, wherein reducing MBr_{b} comprises heating MBr_{b} to a temperature at which MBr_{b} thermally decomposes into M and Br₂.
